(19) United States
(12) Patent Application Publication
(10) Pub. No.: US 2025/0287816 A1
(43) Pub. Date: Sep. 11, 2025

(54) DISPLAY DEVICE AND MOBILE ELECTRONIC DEVICE INCLUDING THE SAME

(71) Applicant: Samsung Display Co., LTD., Yongin-si (KR)

(72) Inventor: Chun Gi YOU, Yongin-si (KR)

(21) Appl. No.: 18/999,790

(22) Filed: Dec. 23, 2024

(30) Foreign Application Priority Data
Mar. 6, 2024 (KR) 10-2024-0032011

(51) Int. Cl. H10K 59/80; G02B 27/01; H10K 59/122

(52) U.S. Cl. CPC H10K 59/873; G02B 27/0172; H10K 59/122; G02B 2027/0178

(57) ABSTRACT

A display device includes a display panel having a display area and a non-display area outside the display area. The display panel includes a light emitting element in the display area and a dam structure in the non-display area. The dam structure includes a dam separator penetrating an insulating film on a substrate of the display panel, a dam insulating film on the insulating film around the dam separator, and an encapsulation layer covering the dam insulating film and the dam separator, and the dam insulating film has a tapered shape having a decreasing width from a surface of the insulating film toward a top thereof.

### CROSS-REFERENCE TO RELATED APPLICATION

This application claims priority to and the benefit of Korean Patent Application No. 10-2024-0032011, filed on Mar. 6, 2024, in the Korean Intellectual Property Office, the contents of which are herein incorporated in their entirety by reference.

### BACKGROUND

### 1. Field

Aspects of embodiments of the present disclosure relate to a display device and a mobile electronic device including the same.

### 2. Description of the Related Art

Wearable devices in which a focus is formed at a distance close to a user's eyes have been developed in the form of glasses or a helmet. For example, the wearable device may be a head mounted display (HMD) device or AR glasses. The wearable device may provide an augmented reality (hereinafter, referred to as “AR”) screen or a virtual reality (hereinafter, referred to as “VR”) screen to a user. The wearable devices, such as the HMD device or the AR glasses, ideally

have a display specification of at least 2000 PPI (pixels per inch) so that a user may use it for a long time without dizziness. To this end, organic light emitting diode on silicon (OLEDoS) technology, which features a high-resolution, small organic light emitting display device, is emerging. In an OLEDoS display panel, a display element layer including a light emitting element is disposed on a semiconductor wafer substrate on which a complementary metal oxide semiconductor (CMOS) is disposed, and the display element layer is covered with an encapsulation layer.

The encapsulation layer is disposed to extend to a dam area, which is in a non-display area of the display panel, to prevent oxygen or moisture from permeating into the display element layer.

### SUMMARY

Embodiments of the present disclosure provide a display device capable of preventing oxygen or moisture from permeating into a display element layer by preventing a crack in an encapsulation layer in a dam area of a display panel and also provide a mobile electronic device including the same.

However, aspects and features of the present disclosure are not limited to those set forth herein. The above and other aspects and features of the present disclosure will become more apparent to one of ordinary skill in the art to which the present disclosure pertains by referencing the detailed description of the present disclosure given below.

According to an embodiment of the present disclosure, a display device includes: a display panel having a display area and a non-display area outside the display area, the display panel including a light emitting element in the light emitting area and a dam structure in the non-display area. The dam structure includes a dam separator penetrating an insulating film on a substrate of the display panel, a dam insulating film on the insulating film around the dam separator, and an encapsulation layer covering the dam insulating film and the dam separator, and the dam insulating film has a tapered shape having a decreasing width from a surface of the insulating film toward a top thereof.

The dam insulating film may include a first dam insulating film on the insulating film, a second dam insulating film on the first dam insulating film, and a third dam insulating film on the second dam insulating film.

The first dam insulating film may have a first width, the second dam insulating film may have a second width that is smaller than the first width, and the third dam insulating film may have a third width that is smaller than the second width.

The light emitting element may include a first electrode, a light emitting stack, and a second electrode sequentially stacked on the insulating film. An edge of the first electrode may be covered by a pixel defining film, and the pixel defining film may be on the same layer as the dam insulating film.

The pixel defining film may include a first pixel defining film on the insulating film, a second pixel defining film on the first pixel defining film, and a third pixel defining film on the second pixel defining film.

A width of the first pixel defining film at a periphery of the light emitting element may greater than a width of the second pixel defining film and a width of the third pixel defining film, and a width of the second pixel defining film may be greater than a width of the third pixel defining film.

The first dam insulating film may be on the same layer as the first pixel defining film, the second dam insulating film may be on the same layer as the second pixel defining film, and the third dam insulating film may be on the same layer as the third pixel defining film.

Each of the first to third dam insulating films may be an inorganic film including silicon oxide (SiOₓ).

A thickness of each of the first to third dam insulating films may be 500 Å.

The encapsulation layer may include a first encapsulation inorganic film and a second encapsulation inorganic film on the first encapsulation inorganic film.

According to another embodiment of the present disclosure, a mobile electronic device includes: a display panel having a display area and a non-display area outside the display area, the display panel includes a light emitting element in the display area and a dam structure in the non-display area. The dam structure includes a dam separator penetrating an insulating film on a substrate of the display panel, a dam insulating film on the insulating film around the dam separator, and an encapsulation layer covering the dam insulating film and the dam separator, and the dam insulating film has a tapered shape having a decreasing width from a surface of the insulating film toward a top thereof.

The dam insulating film may include a first dam insulating film on the insulating film, a second dam insulating film on the first dam insulating film, and a third dam insulating film on the second dam insulating film.

The first dam insulating film may have a first width, the second dam insulating film may have a second width that is smaller than the first width, and the third dam insulating film may have a third width that is smaller than the second width.

The light emitting element may include a first electrode, a light emitting stack, and a second electrode sequentially stacked on the insulating film. An edge of the first electrode may be covered by a pixel defining film, and the pixel defining film may be on the same layer as the dam insulating film.

The pixel defining film may include a first pixel defining film on the insulating film, a second pixel defining film on the first pixel defining film, and a third pixel defining film on the second pixel defining film.

A width of the first pixel defining film at a periphery of the light emitting element may be greater than a width of the second pixel defining film and a width of the third pixel defining film, and a width of the second pixel defining film may be greater than a width of the third pixel defining film.

The first dam insulating film may be on the same layer as the first pixel defining film, the second dam insulating film may be on the same layer as the second pixel defining film, and the third dam insulating film may be on the same layer as the third pixel defining film.

Each of the first to third dam insulating films may be an inorganic film including silicon oxide (SiOₓ).

A thickness of each of the first to third dam insulating films may be 500 Å.

The encapsulation layer may include a first encapsulation inorganic film and a second encapsulation inorganic film on the first encapsulation inorganic film.

According to embodiments of the present disclosure, a display device and a mobile electronic device including the same may prevent oxygen or moisture from permeating into a display element layer by preventing a crack in an encapsulation layer in a dam area of a display panel.

However, aspects and features of embodiments of the present disclosure are not limited to those explained above and various other aspects and features are incorporated herein.

### BRIEF DESCRIPTION OF THE DRAWINGS

The above and other aspects and features of the present disclosure will become more apparent by describing, in detail, embodiments thereof with reference to the attached drawings, in which:

FIG. 1 is an exploded perspective view of a display device according to one embodiment;

FIG. 2 is a block diagram describing a display device according to one embodiment;

FIG. 3 is an equivalent circuit diagram of a first sub-pixel according to one embodiment;

FIG. 4 is a layout diagram illustrating a display panel according to one embodiment;

FIGS. 5 and 6 are layout diagrams of the display area shown in FIG. 4 according to various embodiments;

FIG. 7 is a cross-sectional view of a display panel taken along the line 11-11′ in FIG. 5;

FIG. 8 is a perspective view of a head mounted display according to one embodiment;

FIG. 9 is an exploded perspective view of the head mounted display shown in FIG. 8;

FIG. 10 is a perspective view of a head mounted display according to another embodiment;

FIG. 11 is a diagram illustrating a mother substrate for manufacturing the display panel according to one embodiment;

FIG. 12 is a cross-sectional view of a display panel according to a comparative example taken along the line A-A′ in FIG. 11;

FIG. 13 is a cross-sectional view of a part of the dam area shown in FIG. 12;

FIG. 14 is a cross-sectional view of a display panel according to one embodiment taken along the line A-A′ in FIG. 11; and

FIGS. 15 and 16 are cross-sectional views of a part of the dam area shown in FIG. 14 according to various embodiments.

### DETAILED DESCRIPTION

The present disclosure will now be described more fully hereinafter with reference to the accompanying drawings, in which embodiments of the present disclosure are shown. The present disclosure may, however, be embodied in different forms and should not be construed as limited to the embodiments set forth herein. Rather, these embodiments are provided so that this disclosure will be thorough and complete and will filly convey the scope of the present disclosure to those skilled in the art.

It will be understood that when an element or layer is referred to as being “on,” “connected to,” or “coupled to” another element or layer, it may be directly on, connected, or coupled to the other element or layer or one or more intervening elements or layers may also be present. When an element or layer is referred to as being “directly on,” “directly connected to,” or “directly coupled to” another element or layer, there are no intervening elements or layers present. For example, when a first element is described as being “coupled” or “connected” to a second element, the first element may be directly coupled or connected to the second element or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions, such as “at least one of” and “any one of,” when preceding a list of elements, modify the entire list of elements and do not modify the individual elements of the list. For example, the expression “at least one of a, b, or c” indicates only a, only b, only c, both a and b, both a and c, both b and c, all of a, b, and c, or variations thereof. As used herein, the terms “use,” “using,” and “used” may be considered synonymous with the terms “utilize,” “utilizing,” and “utilized,” respectively. As used herein, the terms “substantially,” “about,” and similar terms are used as terms of approximation and not as terms of degree, and are intended to account for the inherent variations in measured or calculated values that would be recognized by those of ordinary skill in the art.

It will be understood that, although the terms first, second, third, etc. may be used herein to describe various elements, components, regions, layers, and/or sections, these elements, components, regions, layers, and/or sections should not be limited by these terms. These terms are used to distinguish one element, component, region, layer, or section from another element, component, region, layer, or section. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to be limiting of the present disclosure. As used herein, the singular forms “a” and “an” are intended to include the plural forms as well, unless the context clearly indicates otherwise. It will be further understood that the terms “includes,” “including,” “comprises,” and/or “comprising,” when used in this specification, specify the presence of stated features, integers, steps, operations, elements, and/or components but do not preclude the presence or addition of one or more other features, integers, steps, operations, elements, components, and/or groups thereof.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

Also, any numerical range disclosed and/or recited herein is intended to include all sub-ranges of the same numerical precision subsumed within the recited range. For example, a range of “1.0 to 10.0” is intended to include all subranges between (and including) the recited minimum value of 1.0 and the recited maximum value of 10.0, that is, having a minimum value equal to or greater than 1.0 and a maximum value equal to or less than 10.0, such as, for example, 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any sub-range subsumed within the ranges expressly recited herein. All such ranges are intended to be inherently described in this specification such that amending to expressly recite any such subranges would comply with the requirements of 35 U.S.C. § 112(a) and 35 U.S.C. § 132(a).

Hereinafter, embodiments of the present disclosure will be described with reference to the accompanying drawings.

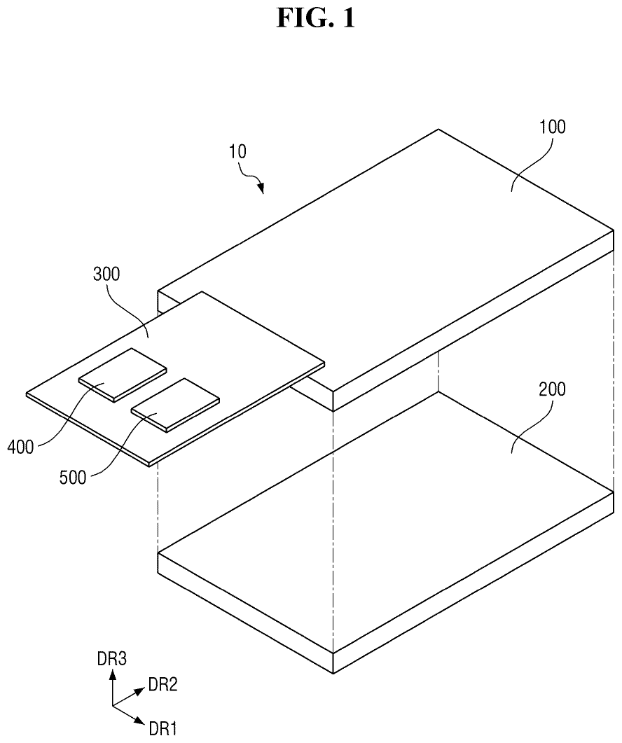

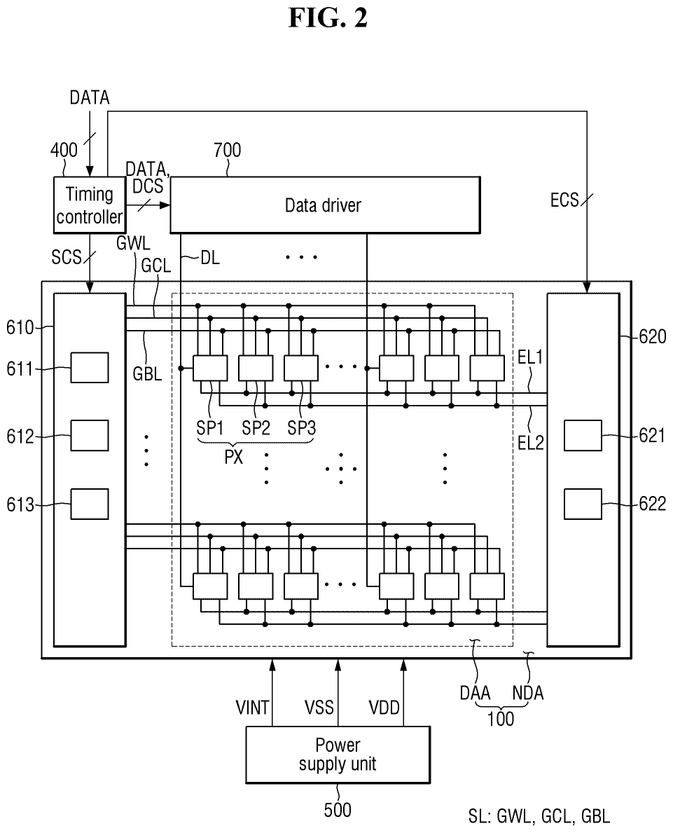

FIG. 1 is an exploded perspective view of a display device according to one embodiment. FIG. 2 is a block diagram describing a display device according to one embodiment.

Referring to FIGS. 1 and 2, a display device 10, according to one embodiment, is a device for displaying a moving image and/or a still image. The display device 10, according to one embodiment, may be applied to portable electronic devices, such as a mobile phone, a smartphone, a tablet personal computer, a mobile communication terminal, an electronic organizer, an electronic book, a portable multimedia player (PMP), a navigation system, an ultra-mobile PC (UMPC), or the like. For example, the display device 10, according to one embodiment, may be applied as (or used as) a display unit of a television, a laptop, a monitor, a billboard, or an Internet-of-Things (IoT) terminal. In other embodiments, the display device 10 may be applied to a smart watch, a watch phone, a head mounted display (HMD) for implementing virtual reality and augmented reality, and the like.

The display device 10, according to one embodiment, includes a display panel 100, a heat dissipation layer 200, a circuit board 300, a timing control circuit 400, and a power supply circuit 500.

The display panel 100 may have a planar shape similar to a quadrilateral shape. For example, the display panel 100 may have a planar shape similar to a quadrilateral shape having a short side in a first direction DR1 and a long side in a second direction DR2 crossing (e.g., intersecting) the first direction DR1. In the display panel 100, a corner at where a short side in the first direction DR1 and a long side in the second direction DR2 meet may be right-angled or rounded with a curvature (e.g., a predetermined curvature). The planar shape of the display panel 100 is not limited to a quadrilateral shape and may be a shape similar to another polygonal shape, a circular shape, or an elliptical shape. The planar shape of the display device 10 may conform to the planar shape of the display panel 100, but embodiments of the present disclosure are not limited thereto.

The display panel 100 has a display area DAA at where an image is displayed and a non-display area NDA at where an image is not displayed as shown in FIG. 2.

The display area DAA includes a plurality of pixels PX, a plurality of scan lines SL, a plurality of emission control lines EL, and a plurality of data lines DL.

The plurality of pixels PX may be arranged in a matrix form in the first direction DR1 and the second direction DR2. The plurality of scan lines SL and the plurality of emission control lines EL may extend in the first direction DR1 while being disposed in (e.g., adjacent to each other in) the second direction DR2. The plurality of data lines DL may extend in the second direction DR2 while being disposed in (e.g., adjacent to each other in) the first direction DR1.

The plurality of scan lines SL include a plurality of write scan lines GWL, a plurality of control scan lines GCL, and a plurality of bias scan lines GBL. The plurality of emission control lines EL include a plurality of first emission control lines EL1 and a plurality of second emission control lines EL2.

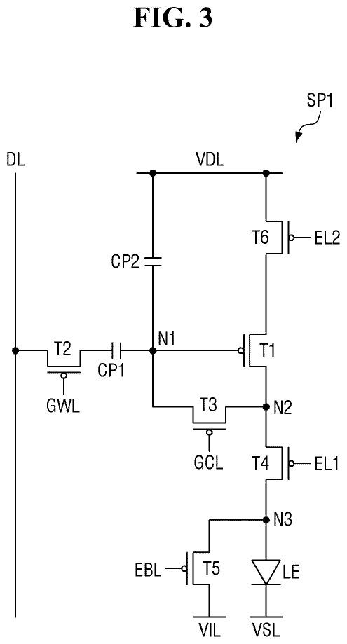

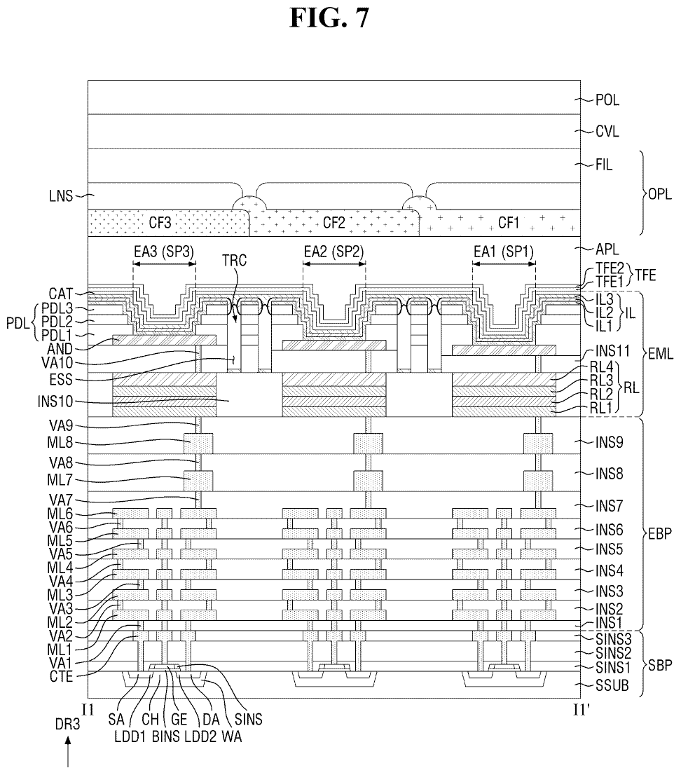

The plurality of pixels PX include a plurality of sub-pixels SP1, SP2, and SP3. The plurality of sub-pixels SP1, SP2, and SP3 may each include a plurality of pixel transistors as shown in, for example, FIG. 3, and the plurality of pixel transistors may be formed by a semiconductor process and disposed on a semiconductor substrate SSUB (see, e.g., FIG. 7). For example, the plurality of pixel transistors of a data driver 700 may be formed of complementary metal oxide semiconductors (CMOS).

Each of the plurality of sub-pixels SP1, SP2, and SP3 may be connected to any one write scan line GWL from among the plurality of write scan lines GWL, any one control scan line GCL from among the plurality of control scan lines GCL, any one bias scan line GBL from among the plurality of bias scan lines GBL, any one first emission control line EL1 from among the plurality of first emission control lines EL1, any one second emission control line EL2 from among the plurality of second emission control lines EL2, and any one data line DL from among the plurality of data lines DL. Each of the plurality of sub-pixels SP1, SP2, and SP3 may receive a data voltage of the data line DL in response to a write scan signal of the write scan line GWL and may emit light from the light emitting element according to the received data voltage.

The non-display area NDA includes a scan driver 610, an emission driver 620, and the data driver 700.

The scan driver 610 includes a plurality of scan transistors, and the emission driver 620 includes a plurality of light emitting transistors. The plurality of scan transistors and the plurality of light emitting transistors may be formed on the semiconductor substrate SSUB (see, e.g., FIG. 7) through a semiconductor process. For example, the plurality of scan transistors and the plurality of light emitting transistors may be formed as CMOS. Although the embodiment shown in FIG. 2 illustrates that the scan driver 610 is disposed on the left side of the display area DAA and the emission driver 620 is disposed on the right side of the display area DAA, embodiments of the present disclosure are not limited thereto. For example, the scan driver 610 and the emission driver 620 may be disposed on both the left side and the right side of the display area DAA.

The scan driver 610 may include a write scan signal output unit 611, a control scan signal output unit 612, and a bias scan signal output unit 613. Each of the write scan signal output unit 611, the control scan signal output unit 612, and the bias scan signal output unit 613 may receive a scan timing control signal SCS from the timing control circuit 400. The write scan signal output unit 611 may generate write scan signals according to the scan timing control signal SCS of the timing control circuit 400 and may output them sequentially to the write scan lines GWL. The control scan signal output unit 612 may generate control scan signals in response to the scan timing control signal SCS and may sequentially output them to the control scan lines GCL. The bias scan signal output unit 613 may generate bias scan signals according to the scan timing control signal SCS and may output them sequentially to bias scan lines EBL.

The emission driver 620 includes a first emission control driver 621 and a second emission control driver 622. Each of the first emission control driver 621 and the second emission control driver 622 may receive an emission timing control signal ECS from the timing control circuit 400. The first emission control driver 621 may generate first emission control signals according to the emission timing control signal ECS and may sequentially output them to the first emission control lines EL1. The second emission control driver 622 may generate second emission control signals according to the emission timing control signal ECS and may sequentially output them to the second emission control lines EL2.

The data driver 700 may include a plurality of data transistors, and the plurality of data transistors may be formed on the semiconductor substrate SSUB (see, e.g., FIG. 7) through a semiconductor process. For example, the plurality of data transistors may be formed as CMOS.

The data driver 700 may receive digital video data DATA and a data timing control signal DCS from the timing control circuit 400. The data driver 700 converts the digital video data DATA into analog data voltages according to the data timing control signal DCS and outputs the analog data voltages to the data lines DL. In such an embodiment, the sub-pixels SP1, SP2, and SP3 are selected by the write scan signal of the scan driver 610, and data voltages may be supplied to the selected sub-pixels SP1, SP2, and SP3.

The heat dissipation layer 200 may overlap the display panel 100 in a third direction DR3, which is the thickness direction of the display panel 100. The heat dissipation layer 200 may be disposed on one surface of the display panel 100, for example, on the rear surface thereof. The heat dissipation layer 200 dissipates heat generated in (or generated by) the display panel 100. The heat dissipation layer 200 may include a metal layer, such as graphite, silver (Ag), copper (Cu), or aluminum (Al) having relatively high thermal conductivity.

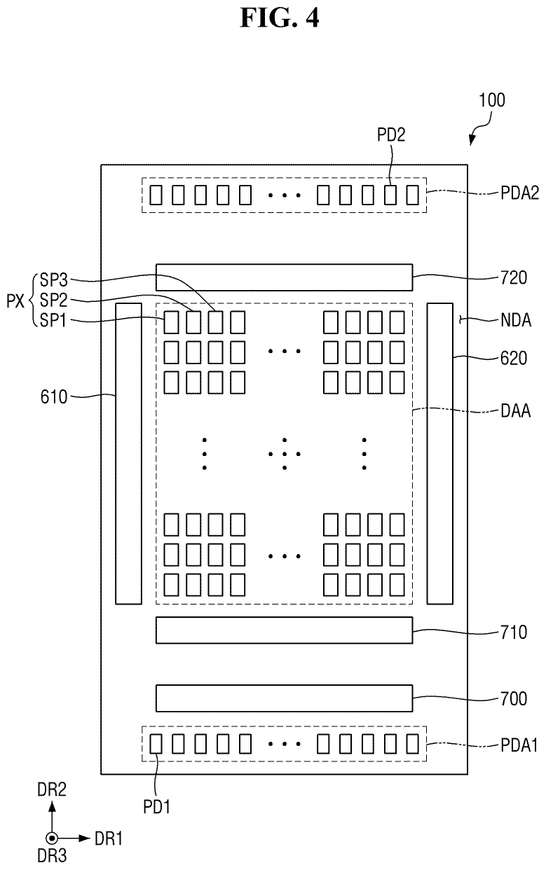

The circuit board 300 may be electrically connected to a plurality of first pads PD1 (see, e.g., FIG. 4) of a first pad portion PDA1 of the display panel 100 by using a conductive adhesive member, such as an anisotropic conductive film. The circuit board 300 may be a flexible printed circuit board formed of a flexible material or may be a flexible film. Although the circuit board 300 is illustrated in FIG. 1 in an unfolded state, the circuit board 300 may be bent. In the bent state, one end of the circuit board 300 may be disposed on the rear surface of the display panel 100 and/or the rear surface of the heat dissipation layer 200. One end of the circuit board 300 may be an opposite end of the other end of the circuit board 300 connected to the plurality of first pads PD1 (see, e.g., FIG. 4) of the first pad portion PDA1 of the display panel 100 by using a conductive adhesive member.

The timing control circuit 400 may receive digital video data and timing signals inputted from the outside. The timing control circuit 400 may generate the scan timing control signal SCS, the emission timing control signal ECS, and the data timing control signal DCS for controlling the display panel 100 in response to the timing signals. The timing control circuit 400 may output the scan timing control signal SCS to the scan driver 610 and may output the emission timing control signal ECS to the emission driver 620. The timing control circuit 400 may output the digital video data and the data timing control signal DCS to the data driver 700.

The power supply circuit 500 may generate a plurality of panel driving voltages according to a power voltage from the outside. For example, the power supply circuit 500 may generate a first driving voltage VSS, a second driving voltage VDD, and a third driving voltage VINT and may supply them to the display panel 100. The first driving voltage VSS, the second driving voltage VDD, and the third driving voltage VINT will be described in more detail later in conjunction with FIG. 3.

Each of the timing control circuit 400 and the power supply circuit 500 may be formed as an integrated circuit (IC) and attached to one surface of the circuit board 300. In such an embodiment, the scan timing control signal SCS, the emission timing control signal ECS, the digital video data DATA, and the data timing control signal DCS of the timing control circuit 400 may be supplied to the display panel 100 through the circuit board 300. Further, the first driving voltage VSS, the second driving voltage VDD, and the third driving voltage VINT of the power supply circuit 500 may be supplied to the display panel 100 through the circuit board 300.

In another embodiment, each of the timing control circuit 400 and the power supply circuit 500 may be disposed in the non-display area NDA of the display panel 100, similarly to the scan driver 610, the emission driver 620, and the data driver 700. In such an embodiment, the timing control circuit 400 may include a plurality of timing transistors, and each power supply circuit 500 may include a plurality of power transistors. The plurality of timing transistors and the plurality of power transistors may be formed on the semiconductor substrate SSUB (see, e.g., FIG. 7) through a semiconductor process. For example, the plurality of timing transistors and the plurality of power transistors may be formed as CMOS. Each of the timing control circuit 400 and the power supply circuit 500 may be disposed between the data driver 700 and the first pad portion PDA1 (see, e.g., FIG. 4).

FIG. 3 is an equivalent circuit diagram of a first sub-pixel according to one embodiment.

Referring to FIG. 3, the first sub-pixel SP1 may be connected to the write scan line GWL, the control scan line GCL, the bias scan line EBL, the first emission control line EL1, the second emission control line EL2, and the data line DL. Further, the first sub-pixel SP1 may be connected to a first driving voltage line VSL to which the first driving voltage VSS corresponding to a low potential voltage is applied, a second driving voltage line VDL to which the second driving voltage VDD corresponding to a high potential voltage is applied, and a third driving voltage line VIL to which the third driving voltage VINT corresponding to an initialization voltage is applied. For example, the first driving voltage line VSL may be a low potential voltage line, the second driving voltage line VDL may be a high potential voltage line, and the third driving voltage line VIL may be an initialization voltage line. In such an embodiment, the first driving voltage VSS may be lower than the third driving voltage VINT, and the second driving voltage VDD may be higher than the third driving voltage VINT.

The first sub-pixel SP1, according to the illustrated embodiment, includes a plurality of transistors T1 to T6, a light emitting element LE, a first capacitor CP1, and a second capacitor CP2.

The light emitting element LE emits light in response to a driving current Ids flowing through the channel of the first transistor T1. The emission amount of the light emitting element LE (e.g., the amount of light emitted by the light emitting element LE) may be proportional to the driving current Ids. The light emitting element LE may be disposed between the fourth transistor T4 and the first driving voltage line VSL. The first electrode of the light emitting element LE may be connected to the drain electrode of the fourth transistor T4, and the second electrode thereof may be connected to the first driving voltage line VSL. The first electrode of the light emitting element LE may be an anode electrode, and the second electrode of the light emitting element LE may be a cathode electrode. The light emitting element LE may be an organic light emitting diode including a first electrode, a second electrode, and an organic light emitting layer disposed between the first electrode and the second electrode, but embodiments of the present disclosure are not limited thereto. For example, the light emitting element LE may be an inorganic light emitting element including a first electrode, a second electrode, and an inorganic semiconductor disposed between the first electrode and the second electrode, in which case the light emitting element LE may be a micro light emitting diode.

The first transistor T1 may be a driving transistor that controls a source-drain current Ids (hereinafter referred to as a “driving current”) flowing between the source electrode and the drain electrode thereof according to a voltage applied to the gate electrode thereof. The first transistor T1 includes a gate electrode connected to a first node N1, a source electrode connected to the drain electrode of the sixth transistor T6, and a drain electrode connected to a second node N2.

The second transistor T2 may be disposed between one electrode of the first capacitor CP1 and the data line DL. The second transistor T2 is turned on by the write scan signal of the write scan line GWL to connect the one electrode of the first capacitor CP1 to the data line DL. Accordingly, the data voltage of the data line DL may be applied to the one electrode of the first capacitor CP1. The second transistor T2 includes a gate electrode connected to the write scan line GWL, a source electrode connected to the data line DL, and a drain electrode connected to the one electrode of the first capacitor CP1.

The third transistor T3 may be disposed between the first node N1 and the second node N2. The third transistor T3 is turned on by the write control signal of the write control line GCL to connect the first node N1 to the second node N2. For this reason, because the gate electrode and the source electrode of the first transistor T1 are connected, the first transistor T1 may operate like a diode. The third transistor T3 includes a gate electrode connected to the write control line GCL, a source electrode connected to the second node N2, and a drain electrode connected to the first node N1.

The fourth transistor T4 may be connected between the second node N2 and a third node N3. The fourth transistor T4 is turned on by the first emission control signal of the first emission control line EL1 to connect the second node N2 to the third node N3. Accordingly, the driving current of the first transistor T1 may be supplied to the light emitting element LE. The fourth transistor T4 includes a gate electrode connected to the first emission control line EL1, a source electrode connected to the second node N2, and a drain electrode connected to the third node N3.

The fifth transistor T5 may be disposed between the third node N3 and the third driving voltage line VIL. The fifth transistor T5 is turned on by the bias scan signal of the bias scan line EBL to connect the third node N3 to the third driving voltage line VIL. Accordingly, the third driving voltage VINT of the third driving voltage line VIL may be applied to the first electrode of the light emitting element LE. The fifth transistor T5 includes a gate electrode connected to the bias scan line EBL, a source electrode connected to the third node N3, and a drain electrode connected to the third driving voltage line VIL.

The sixth transistor T6 may be disposed between the source electrode of the first transistor T1 and the second driving voltage line VDL. The sixth transistor T6 is turned on by the second emission control signal of the second emission control line EL2 to connect the source electrode of the first transistor T1 to the second driving voltage line VDL. Accordingly, the second driving voltage VDD of the second driving voltage line VDL may be applied to the source electrode of the first transistor T1. The sixth transistor T6 includes a gate electrode connected to the second emission control line EL2, a source electrode connected to the second driving voltage line VDL, and a drain electrode connected to the source electrode of the first transistor T1.

The first capacitor CP1 is formed between the first node N1 and the drain electrode of the second transistor T2. The first capacitor CP1 includes one electrode connected to the drain electrode of the second transistor T2 and another electrode connected to the first node N1.

The second capacitor CP2 is formed between the gate electrode of the first transistor T1 and the second driving voltage line VDL. The second capacitor CP2 includes one electrode connected to the gate electrode of the first transistor T1 and another electrode connected to the second driving voltage line VDL.

The first node N1 is a junction between the gate electrode of the first transistor T1, the drain electrode of the third transistor T3, the other electrode of the first capacitor CP1, and the one electrode of the second capacitor CP2. The second node N2 is a junction between the drain electrode of the first transistor T1, the source electrode of the third transistor T3, and the source electrode of the fourth transistor T4. The third node N3 is a junction between the drain electrode of the fourth transistor T4, the source electrode of the fifth transistor T5, and the first electrode of the light emitting element LE.

Each of the first to sixth transistors T1 to T6 may be a metal-oxide-semiconductor field effect transistor (MOSFET). For example, each of the first to sixth transistors T1 to T6 may be a P-type MOSFET, but embodiments of the present disclosure are not limited thereto. Each of the first to sixth transistors T1 to T6 may be an N-type MOSFET. In some embodiments, some of the first to sixth transistors T1 to T6 may be P-type MOSFETs, and each of the remaining transistors may be an N-type MOSFET.

Although the embodiment illustrated in FIG. 3 shows that the first sub-pixel SP1 includes six transistors T1 to T6 and two capacitors C1 and C2, it should be noted that the equivalent circuit diagram of the first sub-pixel SP1 is not limited to that shown in FIG. 3. For example, the number of transistors and the number of capacitors of the first sub-pixel SP1 are not limited to those shown in FIG. 3.

Further, the equivalent circuit diagram of the second sub-pixel SP2 and the equivalent circuit diagram of the third sub-pixel SP3 may be substantially the same as the equivalent circuit diagram of the first sub-pixel SP1 described in conjunction with FIG. 3. Therefore, the description of the equivalent circuit diagram of the second sub-pixel SP2 and the equivalent circuit diagram of the third sub-pixel SP3 is omitted in the present disclosure.

FIG. 4 is a layout view of a display panel according to one embodiment.

Referring to FIG. 4, the display area DAA of the display panel 100, according to one embodiment, includes the plurality of pixels PX arranged in a matrix form. The non-display area NDA of the display panel 100, according to one embodiment, includes the scan driver 610, the emission driver 620, the data driver 700, a first distribution circuit 710, a second distribution circuit 720, the first pad portion PDA1, and a second pad portion PDA2.

The scan driver 610 may be disposed on the first side of the display area DAA, and the emission driver 620 may be disposed on the second side of the display area DAA. For example, the scan driver 610 may be disposed on one side of the display area DAA in the first direction DR1, and the emission driver 620 may be disposed on the other side of the display area DAA in the first direction DR1. For example, the scan driver 610 may be disposed on the left side of the display area DAA, and the emission driver 620 may be disposed on the right side of the display area DAA. However, embodiments of the present disclosure are not limited thereto, and in other embodiments, the scan driver 610 and the emission driver 620 may be disposed on both the first side and the second side of the display area DAA.

The first pad portion PDA1 may include the plurality of first pads PD1 connected to pads or bumps of the circuit board 300 through a conductive adhesive member. The first pad portion PDA1 may be disposed on the third side of the display area DAA. For example, the first pad portion PDA1 may be disposed on one side of the display area DAA in the second direction DR2.

The first pad portion PDA1 may be disposed outside the data driver 700 in the second direction DR2. For example, the first pad portion PDA1 may be disposed closer to the edge of the display panel 100 than the data driver 700 is.

The second pad portion PDA2 may include a plurality of second pads PD2 corresponding to inspection pads that test whether or not the display panel 100 operates normally. The plurality of second pads PD2 may be connected to a jig or a probe pin during an inspection process or may be connected to a circuit board for inspection. The circuit board for inspection may be a printed circuit board made of a rigid material or a flexible printed circuit board made of a flexible material.

The first distribution circuit 710 distributes data voltages applied through the first pad portion PDA1 to the plurality of data lines DL. For example, the first distribution circuit 710 may distribute the data voltages applied through one first pad PD1 of the first pad portion PDA1 to the P (where P is a positive integer of 2 or more) data lines DL, and as a result, the number of the plurality of first pads PD1 may be reduced. The first distribution circuit 710 may be disposed on the third side of the display area DAA of the display panel 100. For example, the first distribution circuit 710 may be disposed on one side of the display area DAA in the second direction DR2. For example, the first distribution circuit 710 may be disposed on the lower side of the display area DAA.

The second distribution circuit 720 distributes signals applied through the second pad portion PDA2 to the scan driver 610, the emission driver 620, and the data lines DL. The second pad portion PDA2 and the second distribution circuit 720 may be configured to inspect the operation of each of the pixels PX in the display area DAA. The second distribution circuit 720 may be disposed on the fourth side of the display area DAA of the display panel 100. For example, the second distribution circuit 720 may be disposed on the other side of the display area DAA in the second direction DR2. For example, the second distribution circuit 720 may be disposed on the upper side of the display area DAA.

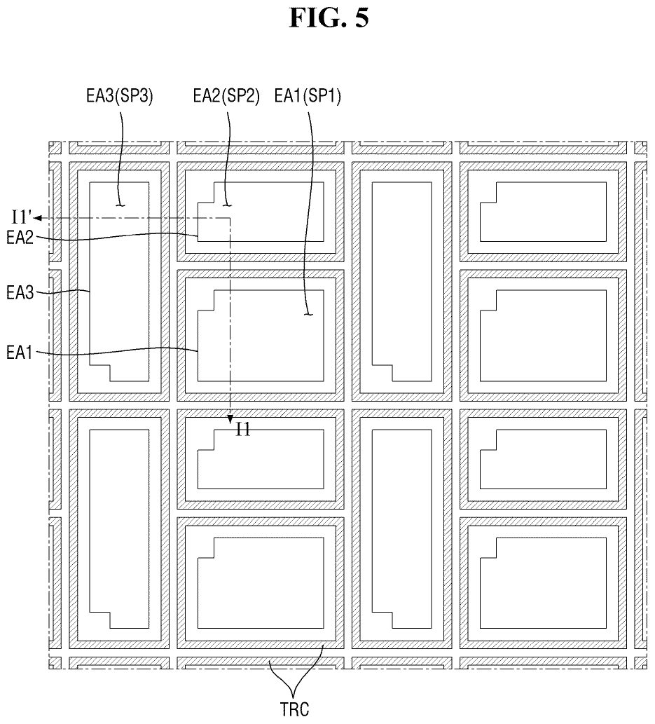

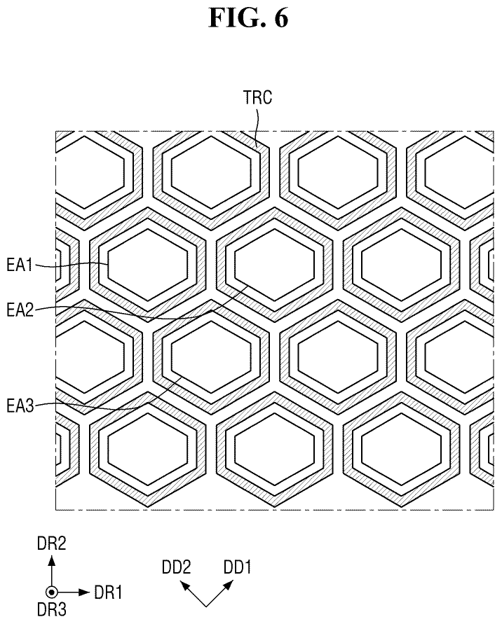

FIGS. 5 and 6 are layout diagrams of the display area shown in FIG. 4 according to various embodiments.

Referring to FIGS. 5 and 6, each of the pixels PX includes the first emission area EA1 that is an emission area of the first sub-pixel SP1, the second emission area EA2 that is an emission area of the second sub-pixel SP2, and the third emission area EA3 that is an emission area of the third sub-pixel SP3.

Each of the first emission area EA1, the second emission area EA2, and the third emission area EA3 may have a polygonal, circular, elliptical, or atypical shape in a plan view.

The maximum length of the first emission area EA1 in the first direction DR1 may be smaller than the maximum length of the second emission area EA2 in the first direction DR1 and the maximum length of the third emission area EA3 in the first direction DR1. The maximum length of the second emission area EA2 in the first direction DR1 and the maximum length of the third emission area EA3 in the first direction DR1 may be substantially the same.

The maximum length of the first emission area EA1 in the second direction DR2 may be greater than the maximum length of the second emission area EA2 in the second direction DR2 and the maximum length of the third emission area EA3 in the second direction DR2. The maximum length of the second emission area EA2 in the second direction DR2 may be greater than the maximum length of the third emission area EA3 in the second direction DR2. The maximum length of the first emission area EA1 in the second direction DR2 may be smaller than the maximum length of the second emission area EA2 in the second direction DR2.

The first emission area EA1, the second emission area EA2, and the third emission area EA3 may have, in a plan view, a hexagonal shape having (or formed of) six straight lines as shown in FIGS. 5 and 6, but embodiments of the present disclosure are not limited thereto. The first emission area EA1, the second emission area EA2, and the third emission area EA3 may have a polygonal shape other than a hexagon, a circular shape, an elliptical shape, or an atypical shape in a plan view.

As shown in FIG. 5, in each of the plurality of pixels PX, the first emission area EA1 and the second emission area EA2 may be adjacent to each other in the first direction DR1. Further, the first emission area EA1 and the third emission area EA3 may be adjacent to each other in the first direction DR1. In addition, the second emission area EA2 and the third emission area EA3 may be adjacent to each other in the second direction DR2. The area of the first emission area EA1, the area of the second emission area EA2, and the area of the third emission area EA3 may be different from each other.

In another embodiment, as shown in FIG. 6, the first emission area EA1 and the second emission area EA2 may be adjacent to each other in the first direction DR1, but the second emission area EA2 and the third emission area EA3 may be adjacent to each other in a first diagonal direction DD1 and the first emission area EA1 and the third emission area EA3 may be adjacent to each other in a second diagonal direction DD2. The first diagonal direction DD1 may be a direction between the first direction DR1 and the second direction DR2 and may refer to a direction inclined by 45 degrees with respect to the first direction DR1 and the second direction DR2, and the second diagonal direction DD2 may be a direction perpendicular to the first diagonal direction DD1.

The first emission area EA1 may emit light of a first color, the second emission area EA2 may emit light of a second color, and the third emission area EA3 may emit light of a third color. In one embodiment, the light of the first color may be light in a blue wavelength band, the light of the second color may be light in a green wavelength band, and the light of the third color may be light in a red wavelength band. For example, the blue wavelength band may be a wavelength band of light having a main peak wavelength in a range of about 370 nm to about 460 nm, the green wavelength band may be a wavelength band of light having a main peak wavelength in a range of about 480 nm to about 560 nm, and the red wavelength band may be a wavelength band of light having a main peak wavelength in a range of about 600 nm to about 750 nm.

In the embodiments shown in FIGS. 5 and 6, each of the plurality of pixels PX includes three emission areas EA1, EA2, and EA3, but embodiments of the present disclosure are not limited thereto. For example, each of the plurality of pixels PX may include four emission areas in other embodiments.

In addition, the layout of the emission areas of the plurality of pixels PX is not limited to that illustrated in FIGS. 5 and 6. For example, the emission areas of the plurality of pixels PX may be disposed in a stripe structure in which the emission areas are arranged in the first direction DR1, a PenTile® (a registered trademark of Samsung Display Co., Ltd.) structure in which the emission areas are arranged in a diamond shape, or a hexagonal structure in which the emission areas having, in a plan view, a hexagonal shape are arranged side by side as shown in FIG. 6.

FIG. 7 is a cross-sectional view of a display panel taken along the line 11-11′ in FIG. 5.

Referring to FIG. 7, the display panel 100 includes a semiconductor backplane SBP, a light emitting element backplane EBP, a display element layer EML, an encapsulation layer TFE, an optical layer OPL, a cover layer CVL, and a polarizing plate POL.

The semiconductor backplane SBP includes the semiconductor substrate SSUB including a plurality of pixel transistors PTR, a plurality of semiconductor insulating films covering the plurality of pixel transistors PTR, and a plurality of contact terminals CTE electrically connected to the plurality of pixel transistors PTR, respectively. The plurality of pixel transistors PTR may be the first to sixth transistors T1 to T6 described with reference to FIG. 4.

The semiconductor substrate SSUB may be a silicon substrate, a germanium substrate, or a silicon-germanium substrate. The semiconductor substrate SSUB may be a substrate doped with a first type impurity. A plurality of well regions WA may be disposed in (or on) the top surface of the semiconductor substrate SSUB. The plurality of well regions WA may be regions doped with a second type impurity. The second type impurity may be different from the aforementioned first type impurity. For example, when the first type impurity is a p-type impurity, the second type impurity may be an n-type impurity. Alternatively, when the first type impurity is an n-type impurity, the second type impurity may be a p-type impurity.

Each of the plurality of well regions WA has a source region SA corresponding to the source electrode of the pixel transistor PTR, a drain region DA corresponding to the drain electrode thereof, and a channel region CH disposed between the source region SA and the drain region DA.

A lower insulating film BINS may be disposed between a gate electrode GE and the well region WA. A side insulating film SINS may be disposed on the side surface of the gate electrode GE. The side insulating film SINS may be disposed on the lower insulating film BINS.

Each of the source region SA and the drain region DA may be a region doped with the first type impurity. The gate electrode GE of the pixel transistor PTR may overlap the well region WA in the third direction DR3. The channel region CH may overlap the gate electrode GE in the third direction DR3. The source region SA may be disposed on one side of the gate electrode GE, and the drain region SA may be disposed on the other side of the gate electrode GE.

Each of the plurality of well regions WA further includes a first low-concentration impurity region LDD1 disposed between the channel region CH and the source region SA, and a second low-concentration impurity region LDD2 disposed between the channel region CH and the drain region DA. The first low-concentration impurity region LDD1 may be a region having a lower impurity concentration than the source region SA due to the lower insulating film BINS. The second low-concentration impurity region LDD2 may be a region having a lower impurity concentration than the drain region DA due to the lower insulating film BINS. The distance between the source region SA and the drain region DA may increase due to the presence of the first low-concentration impurity region LDD1 and the second low-concentration impurity region LDD2. Therefore, the length of the channel region CH of each of the pixel transistors PTR may increase so that punch-through and hot carrier phenomena that might be caused by a short channel may be prevented.

A first semiconductor insulating film SINS1 may be disposed on the semiconductor substrate SSUB. The first semiconductor insulating film SINS1 may be formed of silicon carbonitride (SiCN) or a silicon oxide (SiOₓ)-based inorganic film, but embodiments of the present disclosure are not limited thereto.

A second semiconductor insulating film SINS2 may be disposed on the first semiconductor insulating film SINS1. The second semiconductor insulating film SINS2 may be formed of a silicon oxide (SiOₓ)-based inorganic film, but embodiments of the present disclosure are not limited thereto.

The plurality of contact terminals CTE may be disposed on the second semiconductor insulating film SINS2. Each of the plurality of contact terminals CTE may be connected to any one of the gate electrode GE, the source region SA, and the drain region DA of each of the pixel transistors PTR through holes (e.g., openings) penetrating (or extending through) the first semiconductor insulating film SINS1 and the second semiconductor insulating film INS2. The plurality of contact terminals CTE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them.

A third semiconductor insulating film SINS3 may be disposed on a side surface of each of the plurality of contact terminals CTE. The top surface of each of the plurality of contact terminals CTE may be exposed without being covered by the third semiconductor insulating film SINS3. The third semiconductor insulating film SINS3 may be formed of a silicon oxide (SiOₓ)-based inorganic film, but embodiments of the present disclosure are not limited thereto.

The semiconductor substrate SSUB may be replaced with a glass substrate or a polymer resin substrate, such as polyimide. In such embodiments, thin film transistors may be disposed on the glass substrate or the polymer resin substrate. The glass substrate may be a rigid substrate that does not bend, while the polymer resin substrate may be a flexible substrate that can be bent or curved.

The light emitting element backplane EBP includes a plurality of conductive layers ML1 to ML8, a plurality of vias VA1 to VA9, and a plurality of insulating films INS1 to INS9. In addition, the light emitting element backplane EBP includes a plurality of insulating films INS1 to INS11 disposed between the first to eighth conductive layers ML1 to ML8.

The first to eighth conductive layers ML1 to ML8 connect the plurality of contact terminals CTE exposed from the semiconductor backplane SBP to thereby implement the circuit of the first sub-pixel SP1 shown in, for example, FIG. 4. For example, the first to sixth transistors T1 to T6 are formed on the semiconductor backplane SBP, and the connection of the first to sixth transistors T1 to T6 and the first and second capacitors C1 and C2 is accomplished through the first to eighth conductive layers ML1 to ML8. In addition, the connection between the drain region corresponding to the drain electrode of the fourth transistor T4, the source region corresponding to the source electrode of the fifth transistor T5, and the first electrode of the light emitting element LE is also accomplished through the first to eighth conductive layers ML1 to ML8.

The first insulating film INS1 may be disposed on the semiconductor backplane SBP. Each of the first vias VA1 may penetrate the first insulating film INS1 to be connected to the contact terminal CTE exposed from the semiconductor backplane SBP. Each of the first conductive layers ML1 may be disposed on the first insulating film INS1 and may be connected to the first via VA1.

The second insulating film INS2 may be disposed on the first insulating film INS1 and the first conductive layers ML1. Each of the second vias VA2 may penetrate the second insulating film INS2 and may be connected to the exposed first conductive layer ML1. Each of the second conductive layers ML2 may be disposed on the second insulating film INS2 and may be connected to the second via VA2.

The third insulating film INS3 may be disposed on the second insulating film INS2 and the second conductive layers ML2. Each of the third vias VA3 may penetrate the third insulating film INS3 and may be connected to the exposed second conductive layer ML2. Each of the third conductive layers ML3 may be disposed on the third insulating film INS3 and may be connected to the third via VA3.

A fourth insulating film INS4 may be disposed on the third insulating film INS3 and the third conductive layers ML3. Each of the fourth vias VA4 may penetrate the fourth insulating film INS4 and may be connected to the exposed third conductive layer ML3. Each of the fourth conductive layers ML4 may be disposed on the fourth insulating film INS4 and may be connected to the fourth via VA4.

A fifth insulating film INS5 may be disposed on the fourth insulating film INS4 and the fourth conductive layers ML4. Each of the fifth vias VA5 may penetrate the fifth insulating film INS5 and may be connected to the exposed fourth conductive layer ML4. Each of the fifth conductive layers ML5 may be disposed on the fifth insulating film INS5 and may be connected to the fifth via VA5.

A sixth insulating film INS6 may be disposed on the fifth insulating film INS5 and the fifth conductive layers ML5. Each of the sixth vias VA6 may penetrate the sixth insulating film INS6 and may be connected to the exposed fifth conductive layer ML5. Each of the sixth conductive layers ML6 may be disposed on the sixth insulating film INS6 and may be connected to the sixth via VA6.

A seventh insulating film INS7 may be disposed on the sixth insulating film INS6 and the sixth conductive layers ML6. Each of the seventh vias VA7 may penetrate the seventh insulating film INS7 and may be connected to the exposed sixth conductive layer ML6. Each of the seventh conductive layers ML7 may be disposed on the seventh insulating film INS7 and may be connected to the seventh via VA7.

An eighth insulating film INS8 may be disposed on the seventh insulating film INS7 and the seventh conductive layers ML7. Each of the eighth vias VA8 may penetrate the eighth insulating film INS8 and may be connected to the exposed seventh conductive layer ML7. Each of the eighth conductive layers ML8 may be disposed on the eighth insulating film INS8 and may be connected to the eighth via VA8.

The first to eighth conductive layers ML1 to ML8 and the first to eighth vias VA1 to VA8 may be formed of substantially the same material. The first to eighth conductive layers ML1 to ML8 and the first to eighth vias VA1 to VA8 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The first to eighth vias VA1 to VA8 may be made of substantially the same material. First to eighth insulating films INS1 to INS8 may be formed of a silicon oxide (SiOₓ)-based inorganic film, but embodiments of the present disclosure are not limited thereto.

The thicknesses of the first conductive layer ML1, the second conductive layer ML2, the third conductive layer ML3, the fourth conductive layer ML4, the fifth conductive layer ML5, and the sixth conductive layer ML6 may be larger than the thicknesses of the first via VA1, the second via VA2, the third via VA3, the fourth via VA4, the fifth via VA5, and the sixth via VA6, respectively. The thickness of each of the second conductive layer ML2, the third conductive layer ML3, the fourth conductive layer ML4, the fifth conductive layer ML5, and the sixth conductive layer ML6 may be larger than the thickness of the first conductive layer ML1. The thickness of the second conductive layer ML2, the thickness of the third conductive layer ML3, the thickness of the fourth conductive layer ML4, the thickness of the fifth conductive layer ML5, and the thickness of the sixth conductive layer ML6 may be substantially the same. For example, the thickness of the first conductive layer ML1 may be approximately 1360 Å, the thickness of each of the second conductive layer ML2, the third conductive layer ML3, the fourth conductive layer ML4, the fifth conductive layer ML5, and the sixth conductive layer ML6 may be approximately 1440 Å, and the thickness of each of the first via VA1, the second via VA2, the third via VA3, the fourth via VA4, the fifth via VA5, and the sixth via VA6 may be approximately 1150 Å.

The thickness of each of the seventh conductive layer ML7 and the eighth conductive layer ML8 may be larger than the thickness of the first conductive layer ML1, the thickness of the second conductive layer ML2, the thickness of the third conductive layer ML3, the thickness of the fourth conductive layer ML4, the thickness of the fifth conductive layer ML5, and the thickness of the sixth conductive layer ML6. The thickness of the seventh conductive layer ML7 and the thickness of the eighth conductive layer ML8 may be larger than the thickness of the seventh via VA7 and the thickness of the eighth via VA8, respectively. The thickness of each of the seventh via VA7 and the eighth via VA8 may be larger than the thickness of the first via VA1, the thickness of the second via VA2, the thickness of the third via VA3, the thickness of the fourth via VA4, the thickness of the fifth via VA5, and the thickness of the sixth via VA6. The thickness of the seventh conductive layer ML7 and the thickness of the eighth conductive layer ML8 may be substantially the same. For example, the thickness of each of the seventh conductive layer ML7 and the eighth conductive layer ML8 may be approximately 9000 Å. The thickness of each of the seventh via VA7 and the eighth via VA8 may be approximately 6000 Å.

A ninth insulating film INS9 may be disposed on the eighth insulating film INS8 and the eighth conductive layer ML8. The ninth insulating film INS9 may be formed of a silicon oxide (SiOₓ)-based inorganic film, but embodiments of the present disclosure are not limited thereto.

Each of the ninth vias VA9 may penetrate the ninth insulating film INS9 and may be connected to the exposed eighth conductive layer ML8. The ninth vias VA9 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the ninth via VA9 may be approximately 16500 Å.

The display element layer EML may be disposed on the light emitting element backplane EBP. The display element layer EML may include light emitting elements LE each including a reflective electrode layer RL, tenth and eleventh insulating films INS10 and INS11, a tenth via VA10, the first electrode AND, a light emitting stack IL, and a second electrode CAT, a pixel defining film PDL, and a plurality of trenches TRC.

The reflective electrode layer RL may be disposed on the ninth insulating film INS9. The reflective electrode layer RL may include at least one reflective electrode RL1, RL2, RL3, and RL4. For example, the reflective electrode layer RL may include first to fourth reflective electrodes RL1, RL2, RL3, and RL4 as shown in FIG. 7.

Each of the first reflective electrodes RL1 may be disposed on the ninth insulating film INS9 and may be connected to the ninth via VA9. The first reflective electrodes RL1 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first reflective electrodes RL1 may include titanium nitride (TiN).

Each of the second reflective electrodes RL2 may be disposed on the first reflective electrode RL1. The second reflective electrodes RL2 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the second reflective electrodes RL2 may include aluminum (Al).

Each of the third reflective electrodes RL3 may be disposed on the second reflective electrode RL2. The third reflective electrodes RL3 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the third reflective electrodes RL3 may include titanium nitride (TiN).

The fourth reflective electrodes RL4 may be respectively disposed on the third reflective electrodes RL3. The fourth reflective electrodes RL4 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the fourth reflective electrodes RL4 may include titanium (Ti)

Because the second reflective electrode RL2 is an electrode that substantially reflects light from the light emitting elements LE, the thickness of the second reflective electrode RL2 may be greater than the thickness of each of the first reflective electrode RL1, the third reflective electrode RL3, and the fourth reflective electrode RL4. For example, the thickness of each of the first reflective electrode RL1, the third reflective electrode RL3, and the fourth reflective electrode RL4 may be approximately 100 Å, and the thickness of the second reflective electrode RL2 may be approximately 850 Å.

A tenth insulating film INS10 may be disposed on the ninth insulating film INS9. The tenth insulating film INS10 may be disposed between the reflective electrode layers RL adjacent to each other in a horizontal direction. The tenth insulating film INS10 may be disposed on the reflective electrode layer RL in the third sub-pixel SP3. The tenth insulating film INS10 may be formed of a silicon oxide (SiOₓ)-based inorganic film, but embodiments of the present disclosure are not limited thereto.

An eleventh insulating film INS11 may be disposed on the tenth insulating film INS10 and the reflective electrode layer RL. The eleventh insulating film INS11 may be formed of a silicon oxide (SiOₓ)-based inorganic film, but embodiments of the present disclosure are not limited thereto. The tenth insulating film INS10 and the eleventh insulating film INS11 may be an optical auxiliary layer through which light reflected by the reflective electrode layer RL passes from among light emitted from the light emitting elements LE.

To match the resonance distance of the light emitted from the light emitting elements LE in at least one of the first sub-pixel SP1, the second sub-pixel SP2, or the third sub-pixel SP3, the tenth insulating film INS10 and the eleventh insulating film INS11 may not be disposed under the first electrode AND of the first sub-pixel SP1. The first electrode AND of the first sub-pixel SP1 may be directly disposed on the reflective electrode layer RL. The eleventh insulating film INS11 may be disposed under the first electrode AND of the second sub-pixel SP2. The tenth insulating film INS10 and the eleventh insulating film INS11 may be disposed under the first electrode AND of the third sub-pixel SP3.

Thus, the distance between the first electrode AND and the reflective electrode layer RL may be different in the first sub-pixel SP1, the second sub-pixel SP2, and the third sub-pixel SP3. That is, to adjust the distance from the reflective electrode layer RL to the second electrode CAT according to the main (or primary) wavelength of the light emitted from each of the first sub-pixel SP1, the second sub-pixel SP2, and the third sub-pixel SP3, the presence or absence of the tenth insulating film INS10 and the eleventh insulating film INS11 may be set in each of the first sub-pixel SP1, the second sub-pixel SP2, and the third sub-pixel SP3. For example, in the embodiment illustrated in FIG. 7, the distance between the first electrode AND and the reflective electrode layer RL in the third sub-pixel SP3 is larger than the distance between the first electrode AND and the reflective electrode layer RL in the second sub-pixel SP2 and the distance between the first electrode AND and the reflective electrode layer RL in the first sub-pixel SP1, and the distance between the first electrode AND and the reflective electrode layer RL in the second sub-pixel SP2 is larger than the distance between the first electrode AND and the reflective electrode layer RL in the first sub-pixel SP1, but embodiments of the present disclosure are not limited thereto.

In addition, although the tenth insulating film INS10 and the eleventh insulating film INS11 are illustrated in the embodiment shown in FIG. 7, a twelfth insulating film INS12 disposed under the first electrode AND of the first sub-pixel SP1 may be added. In such an embodiment, the eleventh insulating film INS11 and the twelfth insulating film INS12 may be disposed under the first electrode AND of the second sub-pixel SP2, and the tenth insulating film INS10, the eleventh insulating film INS11, and the twelfth insulating film INS12 may be disposed under the first electrode AND of the third sub-pixel SP3.

Each of the tenth vias VA10 may penetrate the tenth insulating film INS10 and/or the eleventh insulating film INS11 in the second sub-pixel SP2 and the third sub-pixel SP3 and may be connected to the exposed ninth conductive layer ML9. The tenth vias VA10 may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. The thickness of the tenth via VA10 in the second sub-pixel SP2 may be smaller than the thickness of the tenth via VA10 in the third sub-pixel SP3.

The first electrode AND of each of the light emitting elements LE may be disposed on the tenth insulating film INS10 and connected to the tenth via VA10. The first electrode AND of each of the light emitting elements LE may be connected to the drain region DA or source region SA of the pixel transistor PTR through the tenth via VA10, the first to fourth reflective electrodes RL1 to RL4, the first to ninth vias VA1 to VA9, the first to eighth conductive layers ML1 to ML8, and the contact terminal CTE. The first electrode AND of each of the light emitting elements LE may be formed of any one of copper (Cu), aluminum (Al), tungsten (W), molybdenum (Mo), chromium (Cr), gold (Au), titanium (Ti), nickel (Ni), and neodymium (Nd), or an alloy including any one of them. For example, the first electrode AND of each of the light emitting elements LE may be titanium nitride (TiN).

The pixel defining film PDL may be disposed on a part of the first electrode AND of each of the light emitting elements LE. The pixel defining film PDL may cover an edge of the first electrode AND of each of the light emitting elements LE. The pixel defining film PDL may partition the first emission areas EA1, the second emission areas EA2, and the third emission areas EA3.

The first emission area EA1 may be defined as an area in which the first electrode AND, the light emitting stack IL, and the second electrode CAT are sequentially stacked in the first sub-pixel SP1 to emit light. The second emission area EA2 may be defined as an area in which the first electrode AND, the light emitting stack IL, and the second electrode CAT are sequentially stacked in the second sub-pixel SP2 to emit light. The third emission area EA3 may be defined as an area in which the first electrode AND, the light emitting stack IL, and the second electrode CAT are sequentially stacked in the third sub-pixel SP3 to emit light.

The pixel defining film PDL may include first to third pixel defining films PDL1, PDL2, and PDL3. The first pixel defining film PDL1 may be disposed on the edge of the first electrode AND of each of the light emitting elements LE, the second pixel defining film PDL2 may be disposed on the first pixel defining film PDL1, and the third pixel defining film PDL3 may be disposed on the second pixel defining film PDL2. The first pixel defining film PDL1, the second pixel defining film PDL2, and the third pixel defining film PDL3 may be formed of a silicon oxide (SiOₓ)-based inorganic film, but embodiments of the present disclosure are not limited thereto. The first pixel defining film PDL1, the second pixel defining film PDL2, and the third pixel defining film PDL3 may each have a thickness of about 500 Å.

When the first pixel defining film PDL1, the second pixel defining film PDL2, and the third pixel defining film PDL3 are formed as one pixel defining film, the height of the one pixel defining film increases such that a first encapsulation inorganic film TFE1 may be cut off (or separated) due to step coverage. Step coverage refers to the ratio of the degree of thin film coated on an inclined portion to the degree of thin film coated on a flat portion. The lower the step coverage, the more likely it is that the thin film will be cut off at inclined portions.

Therefore, to prevent the first encapsulation inorganic film TFE1 from being cut off due to the step coverage, the first pixel defining film PDL1, the second pixel defining film PDL2, and the third pixel defining film PDL3 may have a cross-sectional structure having a stepped portion. For example, the width of the first pixel defining film PDL1 may be greater than the width of the second pixel defining film PDL2 and the width of the third pixel defining film PDL3, and the width of the second pixel defining film PDL2 may be greater than the width of the third pixel defining film PDL3. The width of the first pixel defining film PDL1 refers to the horizontal length of the first pixel defining film PDL1 defined in the first direction DR1 and the second direction DR2.

Each of the plurality of trenches TRC may penetrate the first pixel defining film PDL1, the second pixel defining film PDL2, and the third pixel defining film PDL3. Furthermore, each of the plurality of trenches TRC may penetrate the eleventh insulating film INS11. The tenth insulating film INS10 may be partially recessed at each of the plurality of trenches TRC.

At least one trench TRC may be disposed between adjacent sub-pixels SP1, SP2, and SP3. Although FIG. 7 illustrates an embodiment in which two trenches TRC are disposed between adjacent sub-pixels SP1, SP2, and SP3, embodiments of the present disclosure are not limited thereto.

The light emitting stack IL may include a plurality of intermediate layers. FIG. 7 illustrates an embodiment in which the light emitting stack IL has a three-tandem structure including the first stack layer IL1, the second stack layer IL2, and the third stack layer IL3, but embodiments of the present disclosure are not limited thereto. For example, the light emitting stack IL may have a two-tandem structure including two intermediate layers.

In the three-tandem structure, the light emitting stack IL may have a tandem structure including a plurality of stack layers IL1, IL2, and IL3 that emit different lights (e.g., different color lights). For example, the light emitting stack IL may include the first stack layer IL1 that emits light of the first color, the second stack layer IL2 that emits light of the third color, and the third stack layer IL3 that emits light of the second color. The first stack layer IL1, the second stack layer IL2, and the third stack layer IL3 may be sequentially stacked.

The first stack layer IL1 may have a structure in which a first hole transport layer, a first organic light emitting layer that emits light of the first color, and a first electron transport layer are sequentially stacked. The second stack layer IL2 may have a structure in which a second hole transport layer, a second organic light emitting layer that emits light of the third color, and a second electron transport layer are sequentially stacked. The third stack layer IL3 may have a structure in which a third hole transport layer, a third organic light emitting layer that emits light of the second color, and a third electron transport layer are sequentially stacked.

A first charge generation layer for supplying charges to the second stack layer IL2 and supplying electrons to the first stack layer IL1 may be disposed between the first stack layer IL1 and the second stack layer IL2. The first charge generation layer may include an N-type charge generation layer that supplies electrons to the first stack layer IL1 and a P-type charge generation layer that supplies holes to the second stack layer IL2. The N-type charge generation layer may include a dopant of a metal material.

A second charge generation layer for supplying charges to the third stack layer IL3 and supplying electrons to the second stack layer IL2 may be disposed between the second stack layer IL2 and the third stack layer IL3. The second charge generation layer may include an N-type charge generation layer that supplies electrons to the second stack layer IL2 and a P-type charge generation layer that supplies holes to the third stack layer IL3.

The first stack layer IL1 may be disposed on the first electrodes AND and the pixel defining film PDL and may be disposed on the bottom surface of each trench TRC. Due to the trench TRC, the first stack layer IL1 may be cut off between adjacent sub-pixels SP1, SP2, and SP3. The second stack layer IL2 may be disposed on the first stack layer IL1. Due to the trench TRC, the second stack layer IL2 may be cut off between adjacent sub-pixels SP1, SP2, and SP3. A cavity ESS (or an empty space) may be formed between the first stack layer IL1 and the second stack layer IL2. The third stack layer IL3 may be disposed on the second stack layer IL2. The third stack layer IL3 is not cut off by the trench TRC and may be disposed to cover the second stack layer IL2 in each of the trenches TRC. For example, in the three-tandem structure, each of the plurality of trenches TRC may be a structure for cutting off the first to second stack layers IL1 and IL2, the first charge generation layer, and the second charge generation layer of the display element layer EML between the sub-pixels SP1, SP2, and SP3 adjacent to each other. In addition, in the two-tandem structure, each of the trenches TRC may be a structure for cutting off the charge generation layer disposed between a lower intermediate layer and an upper intermediate layer, and the lower intermediate layer.

To stably cut off the first and second stack layers IL1 and IL2 of the display element layer EML between adjacent sub-pixels SP1, SP2, and SP3, the height of each of the plurality of trenches TRC may be greater than the height of the pixel defining film PDL. The height of each of the plurality of trenches TRC refers to the length of each of the plurality of trenches TRC in the third direction DR3. The height of the pixel defining film PDL refers to the length of the pixel defining film PDL in the third direction DR3. To cut off the first to third stack layers IL1, IL2, and IL3 of the display element layer EML between the neighboring sub-pixels SP1, SP2, and SP3, another structure may be used in place of the trench TRC. For example, instead of the trench TRC, a reverse tapered partition wall may be disposed on the pixel defining film PDL. The number of the stack layers IL1, IL2, and IL3 that emit different lights is

not limited to that shown in FIG. 7. For example, the light emitting stack IL may include two intermediate layers. In such an embodiment, one of the two intermediate layers may be substantially the same as the first stack layer IL1, and the other may include a second hole transport layer, a second organic light emitting layer, a third organic light emitting layer, and a second electron transport layer. In such an embodiment, a charge generation layer for supplying electrons to one intermediate layer and supplying charges to the other intermediate layer may be disposed between the two intermediate layers.

In addition, FIG. 7 illustrates an embodiment in which the first to third stack layers IL1, IL2, and IL3 are all disposed in the first emission area EA1, the second emission area EA2, and the third emission area EA3, but embodiments of the present disclosure are not limited thereto. For example, the first stack layer IL1 may be disposed in the first emission area EA1 and may not be disposed in the second emission area EA2 and the third emission area EA3. Furthermore, the second stack layer IL2 may be disposed in the second emission area EA2 and may not be disposed in the first emission area EA1 and the third emission area EA3. Further, the third stack layer IL3 may be disposed in the third emission area EA3 and may not be disposed in the first emission area EA1 and the second emission area EA2. In such an embodiment, first to third color filters CF1, CF2, and CF3 of the optical layer OPL may be omitted.

The second electrode CAT may be disposed on the third stack layer IL3. The second electrode CAT may be disposed on the third stack layer IL3 in each of the plurality of trenches TRC. The second electrode CAT may be formed of a transparent conductive material (TCO), such as ITO or IZO, that can transmit light or a semi-transmissive conductive material, such as magnesium (Mg), silver (Ag), or an alloy of Mg and Ag. When the second electrode CAT is formed of a semi-transmissive conductive material, the light emission efficiency may be improved in each of the first to third sub-pixels SP1, SP2, and SP3 due to a micro-cavity effect.

The encapsulation layer TFE may be disposed on the display element layer EML. The encapsulation layer TFE may include at least one inorganic film TFE1 and TFE2 to prevent oxygen or moisture from permeating into the display element layer EML. For example, the encapsulation layer TFE may include the first encapsulation inorganic film TFE1, and a second encapsulation inorganic film TFE2.

The first encapsulation inorganic film TFE1 may be disposed on the second electrode CAT. The first encapsulation inorganic film TFE1 may be formed as a multilayer in which one or more inorganic films selected from silicon nitride (SiNₓ), silicon oxy nitride (SiON), and silicon oxide (SiOₓ) are alternately stacked. The first encapsulation inorganic film TFE1 may be formed by a chemical vapor deposition (CVD) process.

The second encapsulation inorganic film TFE2 may be disposed on the first encapsulation inorganic film TFE1. The second encapsulation inorganic film TFE2 may be formed of titanium oxide (TiOₓ) or aluminum oxide (AlOₓ), but embodiments of the present disclosure are not limited thereto. The second encapsulation inorganic film TFE2 may be formed by an atomic layer deposition (ALD) process. The thickness of the second encapsulation inorganic film TFE2 may be smaller than the thickness of the first encapsulation inorganic film TFE1.

An organic film APL may be a layer for increasing the interfacial adhesion between the encapsulation layer TFE and the optical layer OPL. The organic film APL may be an organic film, such as acrylic resin, epoxy resin, phenolic resin, polyamide resin, or polyimide resin.

The optical layer OPL includes a plurality of color filters CF1, CF2, and CF3, a plurality of lenses LNS, and a filling layer FIL. The plurality of color filters CF1, CF2, and CF3 may include the first to third color filters CF1, CF2, and CF3. The first to third color filters CF1, CF2, and CF3 may be disposed on the adhesive layer ADL.

The first color filter CF1 may overlap the first emission area EA1 of the first sub-pixel SP1. The first color filter CF1 may transmit light of the first color (e.g., light in a blue wavelength band). The blue wavelength band may be in a range of approximately 370 nm to approximately 460 nm. Thus, the first color filter CF1 may transmit light of the first color from among light emitted from the first emission area EA1.

The second color filter CF2 may overlap the second emission area EA2 of the second sub-pixel SP2. The second color filter CF2 may transmit light of the second color (e.g., light in a green wavelength band). The green wavelength band may be in a range of approximately 480 nm to approximately 560 nm. Thus, the second color filter CF2 may transmit light of the second color from among light emitted from the second emission area EA2.

The third color filter CF3 may overlap the third emission area EA3 of the third sub-pixel SP3. The third color filter CF3 may transmit light of the third color (e.g., light in a red wavelength band). The red wavelength band may be in a range of approximately 600 nm to approximately 750 nm. Thus, the third color filter CF3 may transmit light of the third color from among light emitted from the third emission area EA3.

The plurality of lenses LNS may be disposed on the first color filter CF1, the second color filter CF2, and the third color filter CF3, respectively. Each of the plurality of lenses LNS may be a structure for increasing a ratio of light directed to the front of the display device 10. Each of the plurality of lenses LNS may have a cross-sectional shape that is convex in an upward direction.

The filling layer FIL may be disposed on the plurality of lenses LNS. The filling layer FIL may have a refractive index (e.g., a predetermined refractive index) such that light travels in the third direction DR3 at an interface between the filling layer FIL and the plurality of lenses LNS. Further, the filling layer FIL may be a planarization layer. The filling layer FIL may be an organic film, such as acrylic resin, epoxy resin, phenolic resin, polyamide resin, or polyimide resin.

The cover layer CVL may be disposed on the filling layer FIL. The cover layer CVL may be a glass substrate or a polymer resin. When the cover layer CVL is a glass substrate, it may be attached onto the filling layer FIL. In such an embodiment, the filling layer FIL may bond the cover layer CVL to the underlying layers. When the cover layer CVL is a glass substrate, it may act as an encapsulation substrate. When the cover layer CVL is a polymer resin, it may be directly applied onto the filling layer FIL.

The polarizing plate may be disposed on one surface of the cover layer CVL. The polarizing plate may be a structure for preventing visibility degradation caused by reflection of external light. The polarizing plate may include a linear polarizing plate and a phase retardation film. For example, the phase retardation film may be a N/4 plate (a quarter-wave plate), but embodiments of the present disclosure are not limited thereto. However, when visibility degradation caused by reflection of external light is sufficiently overcome by using the first to third color filters CF1, CF2, and CF3, the polarizing plate may be omitted.

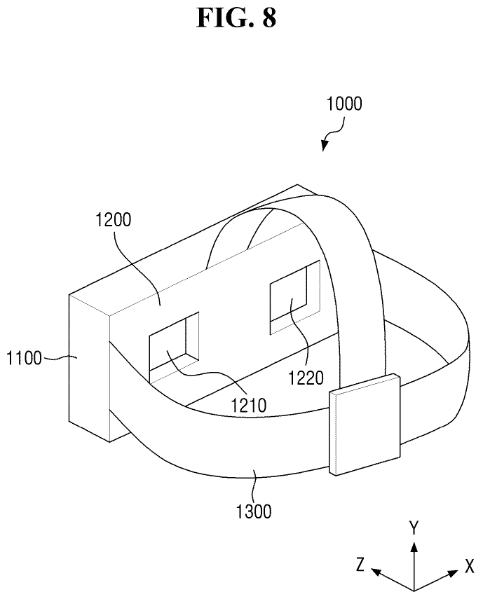

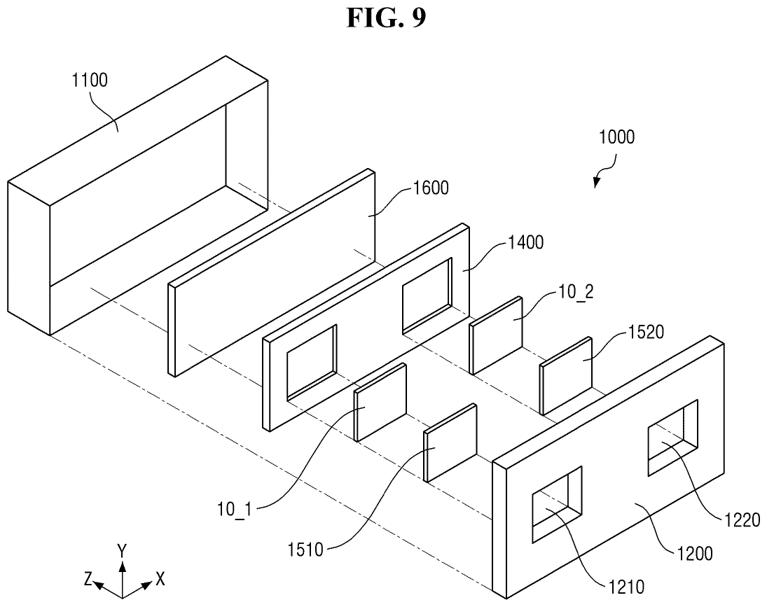

FIG. 8 is a perspective view of a head mounted display according to one embodiment. FIG. 9 is an exploded perspective view of the head mounted display shown in FIG. 8.

Referring to FIGS. 8 and 9, a head mounted display 1000, according to one embodiment, includes a first display device 10_1, a second display device 10_2, a display device housing 1100, a housing cover 1200, a first eyepiece 1210, a second eyepiece 1220, a head mounted band 1300, a middle frame 1400, a first optical member 1510, a second optical member 1520, and a control circuit board 1600.

The first display device 10_1 provides an image to the user's left eye, and the second display device 10_2 provides an image to the user's right eye. Because each of the first display device 10_1 and the second display device 10_2 is substantially the same as the display device 10 described in conjunction with FIGS. 1 and 2, a description of the first display device 10_1 and the second display device 10_2 will be omitted.

The first optical member 1510 may be disposed between the first display device 10_1 and the first eyepiece 1210. The second optical member 1520 may be disposed between the second display device 10_2 and the second eyepiece 1220. Each of the first optical member 1510 and the second optical member 1520 may include at least one convex lens.

The middle frame 1400 may be disposed between the first display device 10_1 and the control circuit board 1600 and between the second display device 10_2 and the control circuit board 1600. The middle frame 1400 supports and fixes the first display device 10_1, the second display device 10_2, and the control circuit board 1600 together.

The control circuit board 1600 may be disposed between the middle frame 1400 and the display device housing 1100. The control circuit board 1600 may be connected to the first display device 10_1 and the second display device 10_2 through the connector. The control circuit board 1600 may convert an image source inputted from the outside into the digital video data DATA and transmit the digital video data

DATA to the first display device 10_1 and the second display device 10_2 through the connector.

The control circuit board 1600 may transmit the digital video data DATA corresponding to a left-eye image optimized for the user's left eye to the first display device 10_1 and may transmit the digital video data DATA corresponding to a right-eye image optimized for the user's right eye to the second display device 10_2. In another embodiment, the control circuit board 1600 may transmit the same digital video data DATA to the first display device 10_1 and the second display device 10_2.

The display device housing 1100 accommodates the first display device 10_1, the second display device 10_2, the middle frame 1400, the first optical member 1510, the second optical member 1520, and the control circuit board 1600. The housing cover 1200 is disposed to cover one open surface of the display device housing 1100. The housing cover 1200 may include the first eyepiece 1210 at where the user's left eye is disposed and the second eyepiece 1220 at where the user's right eye is disposed. FIGS. 8 and 9 illustrate that the first eyepiece 1210 and the second eyepiece 1220 are disposed separately, but embodiments of the present disclosure are not limited thereto. The first eyepiece 1210 and the second eyepiece 1220 may be combined into one.

The first eyepiece 1210 may be aligned with the first display device 10_1 and the first optical member 1510, and the second eyepiece 1220 may be aligned with the second display device 10_2 and the second optical member 1520. Therefore, the user may view, through the first eyepiece 1210, the image of the first display device 10_1 magnified as a virtual image by the first optical member 1510, and may view, through the second eyepiece 1220, the image of the second display device 10_2 magnified as a virtual image by the second optical member 1520.

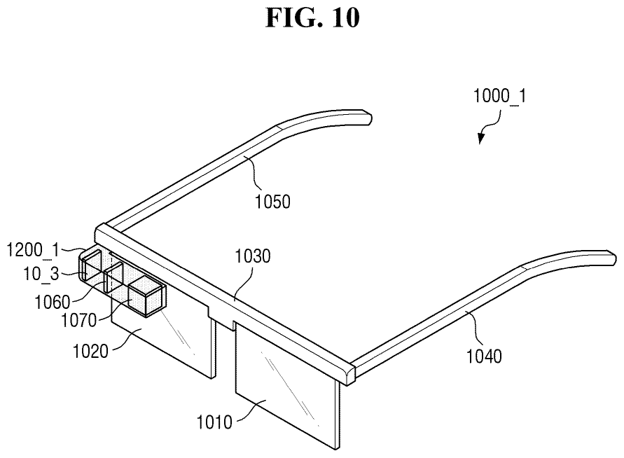

The head mounted band 1300 secures the display device housing 1100 to the user's head such that the first eyepiece 1210 and the second eyepiece 1220 of the housing cover 1200 remain disposed on (e.g., in front of) the user's left and right eyes, respectively. When the display device housing 1200 is implemented to be lightweight and compact, the head mounted display 1000 may be provided with, as shown in FIG. 10, an eyeglass frame instead of the head mounted band 1300.

In addition, the head mounted display 1000 may further include a battery for supplying power, an external memory slot for accommodating an external memory, and an external connection port and a wireless communication module for receiving an image source. The external connection port may be a universe serial bus (USB) terminal, a display port, or a high-definition multimedia interface (HDMI) terminal, and the wireless communication module may be a 5G communication module, a 4G communication module, a Wi-Fi module, or a Bluetooth module.

FIG. 10 is a perspective view illustrating a head mounted display according to another embodiment.

Referring to FIG. 10, a head mounted display 1000_1, according to one embodiment, may be an eyeglasses-type display device in which a display device housing 1200_1 is implemented in a lightweight and compact manner. The head mounted display 1000_1, according to one embodiment, may include a display device 10_3, a left eye lens 1010, a right eye lens 1020, a support frame 1030, temples 1040 and 1050, an optical member 1060, an optical path changing member 1070, and the display device housing 1200_1.

The display device housing 1200_1 may include the display device 10_3, the optical member 1060, and the optical path changing member 1070. The image displayed on the display device 10_3 may be magnified by the optical member 1060 and may be provided to the user's right eye through the right eye lens 1020 after the optical path thereof is changed by the optical path changing member 1070. As a result, the user may view an augmented reality image, through the right eye, in which a virtual image displayed on the display device 10_3 and a real image seen through the right eye lens 1020 are combined.

FIG. 10 illustrates an embodiment in which the display device housing 1200_1 is disposed at the right end of the support frame 1030, but embodiments of the present disclosure are not limited thereto. For example, the display device housing 1200_1 may be disposed at the left end of the support frame 1030, and in such an embodiment, the image of the display device 10_3 may be provided to the user's left eye. In another embodiment, the display device housing 1200_1 may be disposed at both the left and right ends of the support frame 1030, and in such an embodiment, the user may view the image displayed on the display device 10_3 through both the left and right eyes.

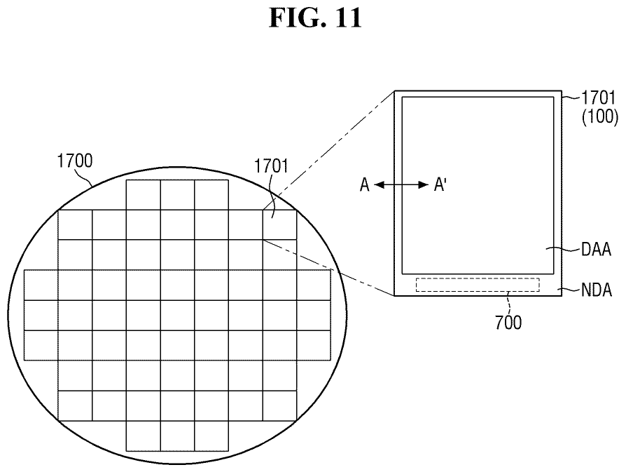

FIG. 11 is a diagram illustrating a mother substrate for manufacturing the display panel 100 according to one embodiment.

Referring to FIG. 10, a mother substrate 1700 may be a semiconductor wafer for manufacturing the OLEDoS display panel 100. In this disclosure, a semiconductor wafer may be referred to as “semiconductor substrate,” “substrate,” or “semiconductor wafer substrate.”

The mother substrate 1700 may include a plurality of net dies 1701, and one net die 1701 may correspond to one display panel 100. For example, the mother substrate 1700, which is a semiconductor wafer, may include about 76 net dies 1701, which means that about 76 display panels 100 may be manufactured from one mother substrate 1700.

The plurality of display panels 100 manufactured based on the mother substrate 1700 may be individually separated by a sawing (or cutting) process and a grinding process in which the corners of each display panel 100 are polished into a round shape.

The display panel 100 may have the display area DAA at where the light emitting element LE is disposed and the non-display area NDA disposed outside the display area DAA.

A driving circuit, such as the data driver 700, may be disposed in the non-display area NDA of the display panel 100. The data driver 700 may be disposed adjacent to one end of the display panel 100 as described in connection with, for example, FIG. 4. In the illustrated embodiment, although the data driver 700 is disposed adjacent to the lower end of the display panel 100, embodiments of the present disclosure are not limited thereto.

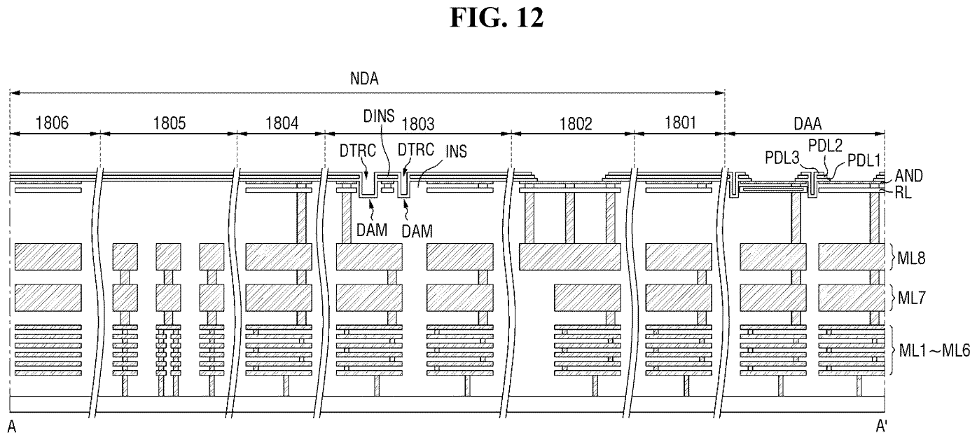

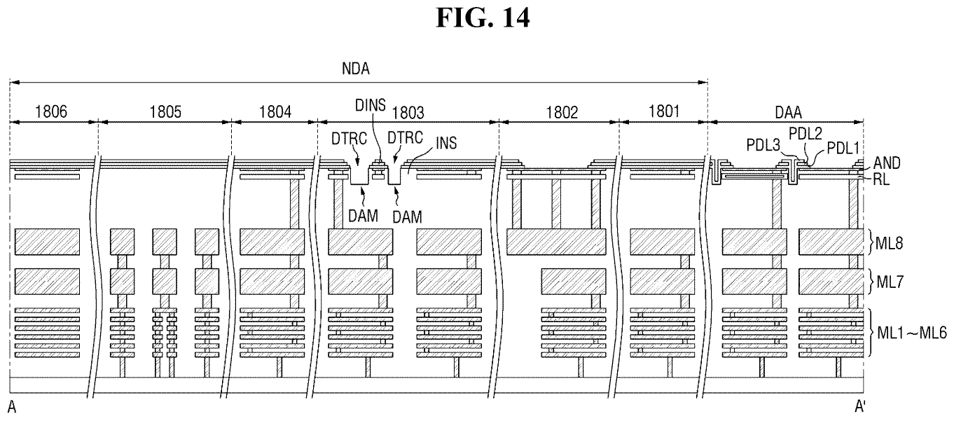

A dam area 1803 (see, e.g., FIG. 12) for preventing infiltration of moisture and oxygen, a moisture permeation/crack prevention area 1805 (see, e.g., FIG. 12), and at least one dummy area 1801, 1804, and 1806 (see, e.g., FIG. 12) are disposed in the non-display area NDA of the display panel 100. The non-display area NDA of the display panel 100 will be described below in detail with reference to FIGS. 12 and 14.

FIG. 12 is a cross-sectional view of the display panel taken along the line A-A′ in FIG. 11 according to a comparative example. In FIG. 12, the pixel defining film PDL is illustrated as the uppermost layer, and the stacked structures (e.g., the encapsulation layer TFE shown in FIG. 7 and the like) disposed on the pixel defining film PDL are omitted.

Referring to FIG. 12, the display panel, according to the comparative example, has the display area DAA at where the light emitting element LE is disposed and the non-display area NDA disposed outside the display area DAA.

According to the comparative example, the non-display area NDA may include a first dummy area 1801, a cathode contact area 1802, the dam area 1803, a second dummy area 1804, the moisture permeation/crack prevention area 1805, and a third dummy area 1806. The non-display area NDA may not include at least one of the first dummy area 1801, the second dummy area 1804, or the third dummy area 1806.

According to the comparative example, the first dummy area 1801 may be disposed closest to the display area DAA, and the third dummy area 1806 may be disposed farthest from the display area DAA. The second dummy area 1804 may be disposed between the first dummy area 1801 and the second dummy area 1804. The dam area 1803 may be disposed between the first dummy area 1801 and the second dummy area 1804. The moisture permeation/crack prevention area 1805 may be disposed between the second dummy area 1804 and the third dummy area 1806.

The cathode contact area 1802 includes a cathode pad to which a second electrode extending from the display area DAA is connected. For example, the second electrode may be connected to the first driving voltage line VSL (see, e.g., FIG. 3) through the cathode contact area 1802.

The dam area 1803 includes at least one dam structure DAM having a dam separator DTRC penetrating the insulating film INS. The dam area 1803 may be a boundary area at where the encapsulation layer TFE covering the display area DAA extends.

The moisture permeation/crack prevention area 1805 blocks oxygen or moisture from flowing into the display panel 100 during a sawing process and a grinding process for the display panel 100.

The third dummy area 1806 may be substantially an area where one display panel 100 is cut in a sawing process.

According to the comparative example, the stacked structure of each of the first dummy area 1801, the cathode contact area 1802, the dam area 1803, the second dummy area 1804, the moisture permeation/crack prevention area 1805, and the third dummy area 1806 is similar to the stacked structure of the semiconductor backplane SBP and the light emitting element backplane EBP disposed in the display area DAA. For example, dummy conductive layers disposed in the same layers as the first to eighth conductive layers ML1 to ML8 (see, e.g., FIG. 7) of the semiconductor backplane SBP and the light emitting element backplane EBP disposed in the display area DAA are disposed in each of the first dummy area 1801, the cathode contact area 1802, the dam area 1803, the second dummy area 1804, the moisture permeation/crack prevention area 1805, and the third dummy area 1806. Reference numerals ML1 to ML8 shown in FIG. 12 denote the dummy conductive layers ML1 to ML8 disposed in the same layers as the first to eighth conductive layers ML1 to ML8 shown in FIG. 7.

According to the comparative example, at least some of the first dummy area 1801, the cathode contact area 1802, the dam area 1803, the second dummy area 1804, the moisture permeation/crack prevention area 1805, and the third dummy area 1806 may further include a dummy reflective electrode disposed in the same layer as the reflective electrode RL disposed in the display area DAA. For example, as shown in FIG. 12, each of the first dummy area 1801, the cathode contact area 1802, the dam area 1803, the second dummy area 1804, and the third dummy area 1806 may further include a dummy reflective electrode disposed in the same layer as the reflective electrode RL (see, e.g., FIG. 7) disposed in the display area DAA. Reference numeral RL shown in FIG. 12 denotes the dummy reflective electrode RL disposed in the same layer as the reflective electrode RL shown in FIG. 7.

According to the comparative example, at least some of the first dummy area 1801, the cathode contact area 1802, the dam area 1803, the second dummy area 1804, the moisture permeation/crack prevention area 1805, and the third dummy area 1806 may include a dummy conductive layer disposed in the same layer as the first electrode AND (see, e.g., FIG. 7) disposed in the display area DAA. Reference numeral AND shown in FIG. 12 denotes the dummy conductive layer AND disposed in the same layer as the first electrode AND shown in FIG. 7.

According to the comparative example, the pixel defining film PDL extending from the display area DAA is disposed on the dummy conductive layer AND in each of the first dummy area 1801, the cathode contact area 1802, the dam area 1803, the second dummy area 1804, the moisture permeation/crack prevention area 1805, and the third dummy area 1806. The pixel defining film PDL may act as a dam insulating film DINS forming the dam structure DAM in the dam area 1803.

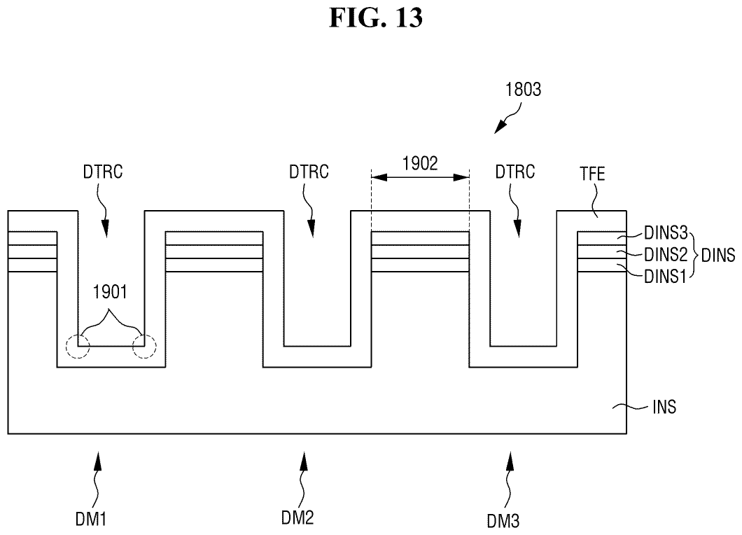

Hereinafter, the stacked structure of the dam area 1803 of the display panel 100 according to the comparative example and shortcomings thereof will be described with reference to FIG. 13.

FIG. 13 is a cross-sectional view showing a part of the dam area 1803 according to the comparative example shown in FIG. 12.

Referring to FIGS. 12 and 13, the dam area 1803 of the display panel according to the comparative example includes at least one dam structure DAM. The dam structure DAM includes the dam separator DTRC penetrating the insulating film INS (e.g., the tenth insulating film INS10 and/or the eleventh insulating film INS11 of FIG. 7) disposed on the substrate (e.g., the semiconductor substrate SSUB of FIG. 7) of the display panel, the dam insulating film DINS disposed on the insulating film INS around the dam separator DTRC, and the encapsulation layer TFE (e.g., the encapsulation layer TFE of FIG. 7) covering the dam insulating film DINS and the dam separator DTRC.

According to the comparative example, the insulating film INS penetrated by the dam separator DTRC may be the tenth insulating film INS10 and the eleventh insulating film INS11 described with reference to FIG. 7.

According to the comparative example, the dam insulating film DINS disposed on the insulating film INS around the dam separator DTRC may be an insulating film disposed in the same layer as the first pixel defining film PDL1, the second pixel defining film PDL2, and the third pixel defining film PDL3 described with reference to FIG. 7. For example, the dam insulating film DINS may include a first dam insulating film DINS1, a second dam insulating film DINS2 disposed on the first dam insulating film DINS1, and a third insulating film INS disposed on the second dam insulating film DINS2. The first dam insulating film DINS1 includes the same material as the first pixel defining film PDL1 and is disposed in the same layer as the first pixel defining film PDL1. The second dam insulating film DINS2 includes the same material as the second pixel defining film PDL2 and is disposed in the same layer as the second pixel defining film PDL2. The third dam insulating film DINS3 includes the same material as the third pixel defining film PDL3 and is disposed in the same layer as the third pixel defining film PDL3.

According to the comparative example, the encapsulation layer TFE is disposed to extend from the display area DAA to the dam area 1803 of the non-display area NDA. For example, the encapsulation layer TFE is disposed to extend from the display area DAA to the first dummy area 1801, the cathode contact area 1802, and the dam area 1803. For example, the encapsulation layer TFE includes the first encapsulation inorganic film (e.g., TFE1 in FIG. 7) and the second encapsulation inorganic film (e.g., TFE2 in FIG. 7), which are disposed to extend to the dam area 1803.

According to the comparative example, in the dam area 1803 of the display panel, the first dam insulating film DINS1, the second dam insulating film DINS2, and the third dam insulating film DINS3 have the same width. In this case, the height from the bottom surface of the dam separator DTRC to the dam insulating film DINS increases such that some layers of the encapsulation layer TFE, such as the first encapsulation inorganic film TFE1 of FIG. 7, may be cut off due to step coverage.

In FIG. 13, reference numeral 1901 denotes a boundary portion of the bottom surface of the dam separator DTRC, and a crack may occur at this boundary portion 1901 at where the encapsulation layer TFE is cut off due to step coverage. The crack in the encapsulation layer TFE may cause permeation of oxygen or moisture into the display element layer EML.

In one embodiment of the present disclosure, the dam insulating film DINS may have a cross-sectional structure with a stepped portion (e.g., a positive tapered structure) to prevent a crack of the encapsulation layer TFE that might be caused in the dam area 1803 of the display panel 100 according to the comparative example. The cross-sectional structure of the dam insulating film DINS according to one embodiment will be described in detail with reference to FIGS. 14 to 16.

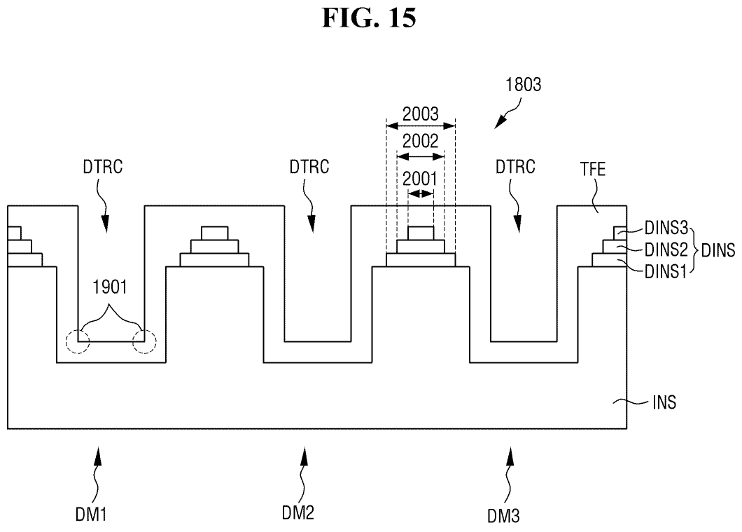

FIG. 14 is a cross-sectional view of the display panel 100 taken along the line A-A′ in FIG. 11 according to one embodiment. FIG. 15 is a cross-sectional view of a part of the dam area 1803 shown in FIG. 14.

The display panel 100, according to one embodiment, illustrated in FIGS. 14 and 15 may be at least partially similar to the display panel according to the comparative example described with reference to FIGS. 12 and 13. The following description will focus on the distinctive features of the embodiment shown in FIGS. 14 and 15 from the display panel according to the comparative example described with reference to FIGS. 12 and 13. Therefore, features not described in FIGS. 14 and 15 can be replaced with the description of the comparative example elaborated above with reference to FIGS. 12 and 13.

Referring to FIGS. 14 and 15, the display panel 100, according to one embodiment, is different from the comparative example shown in FIGS. 12 and 13 in that the dam insulating film DINS has a cross-sectional structure with a stepped portion (e.g., a positive tapered structure).

According to one embodiment, a width 2001 of the first dam insulating film DINS1 is larger than a width 2002 of the second dam insulating film DINS2 and a width 2003 of the third dam insulating film DINS3. Also, the width 2002 of the second dam insulating film DINS2 is larger than the width 2003 of the third dam insulating film DINS3. For example, the first dam insulating film DINS1 may have the first width 2001, the second dam insulating film DINS2 may have the second width 2002 smaller than the first width 2001, and the third dam insulating film DINS3 may have the third width 2003 smaller than the second width 2002.

In the display panel 100, according to one embodiment, step coverage characteristics of (or in) the dam separator DTRC improve because the first to third dam insulating films DINS1 to DINS3 form a cross-sectional structure with the stepped portion in the dam area 1803. In this embodiment, a crack of the encapsulation layer TFE may be prevented during a manufacturing process of forming the encapsulation layer TFE of the display panel 100. For example, in FIG. 15, reference numeral 1901 denotes a boundary portion of the bottom surface of the dam separator DTRC, and the encapsulation layer TFE is not cut off at this boundary portion 1901 due to the stepped structure of the first to third dam insulating films DINS1 to DINS3.

According to one embodiment, the dam insulating film DINS may be an insulating film extending from the pixel defining film PDL disposed in the display area DAA. For example, the first dam insulating film DINS1 includes the same material as the first pixel defining film PDL1 and is disposed in the same layer as the first pixel defining film PDL1. The second dam insulating film DINS2 includes the same material as the second pixel defining film PDL2 and is disposed in the same layer as the second pixel defining film PDL2. The third dam insulating film DINS3 includes the same material as the third pixel defining film PDL3 and is disposed in the same layer as the third pixel defining film PDL3.

According to one embodiment, each of the first dam insulating film DINS1, the second dam insulating film DINS2, and the third dam insulating film DINS3 may be an inorganic film including silicon oxide (SiOₓ), but embodiments of the present disclosure are not limited thereto.

According to one embodiment, each of the first dam insulating film DINS1, the second dam insulating film DINS2, and the third dam insulating film DINS3 may have a thickness of about 500 Å.

In the present disclosure, because the dam separator DTRC is a portion of the dam structure DAM that penetrates a part of the insulating film INS, it may be referred to as “dam trench.”

In the present disclosure, the dam structure DAM may be referred to as “uneven structure.” Although FIGS. 13, 15, and 16 illustrate that three dam structures (e.g., three dam separators DTRC) including a first dam structure DM1, a second dam structure DM2, and a third dam structure DM3 are disposed in the dam area 1803, the present disclosure is not limited thereto. For example, the number of the dam structures (e.g., the dam separators DTRC) disposed in the dam area 1803 of the display panel 100 may be one or more.

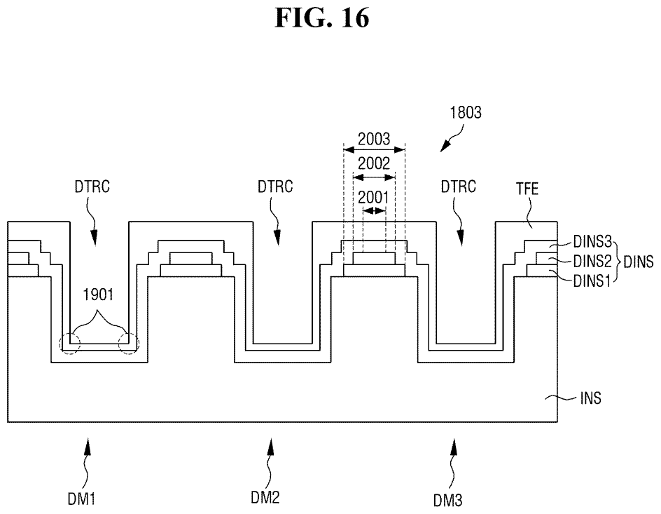

FIG. 16 is a cross-sectional view of a part of the dam area 1803 shown in FIG. 14. For example, FIG. 16 is a cross-sectional view of the dam area 1803 of the display panel 100 according to one embodiment in which the structure of the pixel defining film PDL illustrated in FIG. 15 is modified.

The embodiment shown in FIG. 16 is different from the embodiment shown in FIG. 15 in that the third dam insulating film DINS3 is disposed to cover the entire dam area 1803. For example, the third dam insulating film DINS3 may cover not only the second dam insulating film DINS2 but also the side and bottom surfaces of the dam separator DTRC.

According to one embodiment, the first dam insulating film DINS1 and the second dam insulating film DINS2 included in the dam insulating film DINS may have a cross-sectional structure with a stepped portion (e.g., a positive tapered structure), and the third dam insulating film DINS3 may extend to cover the side and bottom surfaces of the dam separator DTRC as well as the second dam insulating film DINS2. For example, the first dam insulating film DINS1 may have the first width 2001, the second dam insulating film DINS2 may have the second width 2002 smaller than the first width 2001, and the third dam insulating film DINS3 may extend to cover the entire dam area 1803.

In the display panel 100 according to one embodiment, step coverage characteristics in the dam separator DTRC improve as the first and second dam insulating films DINS1 and DINS2 form the cross-sectional structure with the stepped portion in the dam area 1803. In the illustrated embodiment, a crack in the encapsulation layer TFE may be prevented during a manufacturing process of forming the encapsulation layer TFE of the display panel 100. For example, in FIG. 16, reference numeral 1901 denotes a boundary portion of the bottom surface of the dam separator DTRC, and the encapsulation layer TFE is not cut off at this boundary portion 1902 due to the stepped structure of the first and second dam insulating films DINS1 and DINS2.

In concluding the detailed description, those skilled in the art will appreciate that many variations and modifications can be made to the embodiments described herein without substantially departing from the present disclosure. Therefore, the disclosed embodiments of the present disclosure are used in a generic and descriptive sense and not for purposes of limitation.

What is claimed is:

1. A display device comprising:
a display panel having a display area and a non-display area outside the display area, the display panel comprising a light emitting element in the display area and a dam structure in the non-display area,
wherein the dam structure comprises a dam separator penetrating an insulating film on a substrate of the display panel, a dam insulating film on the insulating film around the dam separator, and an encapsulation layer covering the dam insulating film and the dam separator, and
wherein the dam insulating film has a tapered shape having a decreasing width from a surface of the insulating film toward a top thereof.

2. The display device of claim 1, wherein the dam insulating film comprises:
a first dam insulating film on the insulating film;
a second dam insulating film on the first dam insulating film; and
a third dam insulating film on the second dam insulating film.

3. The display device of claim 2, wherein the first dam insulating film has a first width,
wherein the second dam insulating film has a second width that is smaller than the first width, and
wherein the third dam insulating film has a third width that is smaller than the second width.

4. The display device of claim 3, wherein the light emitting element comprises a first electrode, a light emitting stack, and a second electrode sequentially stacked on the insulating film, an edge of the first electrode being covered by a pixel defining film, and
wherein the pixel defining film is on the same layer as the dam insulating film.

5. The display device of claim 4, wherein the pixel defining film comprises:
a first pixel defining film on the insulating film;
a second pixel defining film on the first pixel defining film; and
a third pixel defining film on the second pixel defining film.

6. The display device of claim 5, wherein a width of the first pixel defining film at a periphery of the light emitting element is greater than a width of the second pixel defining film and a width of the third pixel defining film, and
wherein a width of the second pixel defining film is greater than a width of the third pixel defining film.

7. The display device of claim 6, wherein the first dam insulating film is on the same layer as the first pixel defining film,
wherein the second dam insulating film is on the same layer as the second pixel defining film, and
wherein the third dam insulating film is on the same layer as the third pixel defining film.

8. The display device of claim 7, wherein each of the first to third dam insulating films is an inorganic film comprising silicon oxide.

9. The display device of claim 7, wherein a thickness of each of the first to third dam insulating films is 500 Å.

10. The display device of claim 1, wherein the encapsulation layer comprises:
a first encapsulation inorganic film; and
a second encapsulation inorganic film on the first encapsulation inorganic film.

11. A mobile electronic device comprising:
a display panel having a display area and a non-display area outside the display area, the display panel comprising a light emitting element in the display area and a dam structure in the non-display area,
wherein the dam structure comprises a dam separator penetrating an insulating film on a substrate of the display panel, a dam insulating film on the insulating film around the dam separator, and an encapsulation layer covering the dam insulating film and the dam separator, and
wherein the dam insulating film has a tapered shape having a decreasing width from a surface of the insulating film toward a top thereof.

12. The mobile electronic device of claim 11, wherein the dam insulating film comprises:
a first dam insulating film on the insulating film;
a second dam insulating film on the first dam insulating film; and
a third dam insulating film on the second dam insulating film.

13. The mobile electronic device of claim 12, wherein the first dam insulating film has a first width,
wherein the second dam insulating film has a second width that is smaller than the first width, and
wherein the third dam insulating film has a third width that is smaller than the second width.

14. The mobile electronic device of claim 13, wherein the light emitting element comprises a first electrode, a light emitting stack, and a second electrode sequentially stacked on the insulating film, an edge of the first electrode being covered by a pixel defining film, and
wherein the pixel defining film is on the same layer as the dam insulating film.

15. The mobile electronic device of claim 14, wherein the pixel defining film comprises:
a first pixel defining film on the insulating film;
a second pixel defining film on the first pixel defining film; and
a third pixel defining film on the second pixel defining film.

16. The mobile electronic device of claim 15, wherein a width of the first pixel defining film at a periphery of the light emitting element is greater than a width of the second pixel defining film and a width of the third pixel defining film, and
wherein a width of the second pixel defining film is greater than a width of the third pixel defining film.

17. The mobile electronic device of claim 16, wherein the first dam insulating film is on the same layer as the first pixel defining film,
wherein the second dam insulating film is on the same layer as the second pixel defining film, and
wherein the third dam insulating film is on the same layer as the third pixel defining film.

18. The mobile electronic device of claim 17, wherein each of the first to third dam insulating films is an inorganic film comprising silicon oxide.

19. The mobile electronic device of claim 17, wherein a thickness of each of the first to third dam insulating films is 500 Å.

20. The mobile electronic device of claim 11, wherein the encapsulation layer comprises:
a first encapsulation inorganic film; and
a second encapsulation inorganic film on the first encapsulation inorganic film.
